(19) United States
(12) Patent Application Publication
(10) Pub. No.: US 2024/0312963 A1
(43) Pub. Date: Sep. 19, 2024

(54) DISPLAY APPARATUS AND MANUFACTURING METHOD THEREOF

(71) Applicant: SAMSUNG ELECTRONICS CO.. LTD., Suwon-si (KR)

(72) Inventors: Sungjun KOH, Wuwon-si (KR); Sanghyun Sohn, Wuwon-si (KR)

(73) Assignee: SAMSUNG ELECTRONICS CO., LTD., Suwon-si (KR)

(21) Appl. No.: 18/417,639

(22) Filed: Jan. 19, 2024

Related U.S. Application Data
(63) Continuation of application No. PCT/KR2024/000328, filed on Jan. 8, 2024.

(30) Foreign Application Priority Data
Mar. 16, 2023 (KR) 10-2023-0034812
Jun. 27, 2023 (KR) 10-2023-0083021

(51) Int. Cl. H01L 25/075; H01L 33/50

(52) U.S. Cl. CPC H01L 25/0753; H01L 33/505; H01L 2933/0041

(57) ABSTRACT

A method of manufacturing a display module of a display apparatus, includes: forming a sacrificial layer on a base substrate; forming a color filter on the sacrificial layer; forming a color layer by positioning quantum dots on the color filter; adhering to the color layer a light source substrate on which an inorganic light-emitting device is positioned so that the inorganic light-emitting device faces the color layer; and separating the base substrate from the color layer by irradiating the sacrificial layer with laser light.

### CROSS-REFERENCE TO RELATED APPLICATIONS

This application is a by-pass continuation of International Application No. PCT/KR2024/000328, filed on Jan. 8, 2024, which is based on and claims priority to Korean Patent Application No. 10-2023-0034812, filed on Mar. 16, 2023, and Korean Patent Application No. 10-2023-0083021, filed on Jun. 27, 2023, in the Korean Intellectual Property Office, the disclosures of which are incorporated by reference herein in their entireties.

### BACKGROUND

### 1. Field

The disclosure relates to a display apparatus including inorganic light-emitting devices and a manufacturing method thereof.

### 2. Description of Related Art

In general, as a display apparatus, a liquid crystal panel requiring a backlight or an organic light-emitting diode (OLED) panel configured with a film of an organic compound that itself emits light in response to current has been widely used. However, the liquid crystal panel has slow response time and high power consumption, and requires a backlight because the liquid crystal panel itself does not emit light. Accordingly, it is difficult to compactify the liquid crystal panel. Also, although the OLED panel requires no backlight and thus implements a thin thickness because the OLED panel itself emits light, the OLED panel is vulnerable to a burn-in phenomenon in which, in situations where the OLED panel displays the same screen for a long time, a certain area of the screen remains as it is after the screen changes to another screen due to short life cycles of sub pixels. For these reasons, as a new panel for replacing the light crystal panel and the OLED panel, a micro light-emitting diode (micro LED or μLED) panel in which inorganic light-emitting devices are mounted on a substrate and the inorganic light-emitting devices themselves are used as pixels is being studied.

The micro light-emitting diode panel (hereinafter, referred to as a micro LED panel), which is a flat display panel, is configured with a plurality of inorganic LEDs each having a size of 100 micrometers (μm) or less.

The micro LED panel does not cause the burn-in phenomenon of OLEDs as inorganic light-emitting devices that are self-emissive devices, in addition to having excellent brightness, resolution, consumption power, and durability.

The micro LED panel provides better contrast, response time, and energy efficiency than the LCD panel requiring the backlight. Micro LEDs that are inorganic light-emitting devices have higher brightness, higher light-emitting efficiency, and a longer lifespan than OLEDs although both the OLEDs and micro LEDs have high energy efficiency.

In addition, the micro LEDs may achieve a substrate-level display modulation by arranging LEDs on a circuit board in units of pixels, and provide various resolutions and screen sizes according to the customer's order.

### SUMMARY

Provided is a display apparatus that may reduce visibility of seams between a plurality of display modules.

Further, provided is a display apparatus that may reduce light refracted and/or reflected between a plurality of display modules.

Further still, provided is a display apparatus that may simplify a manufacturing process and preventing water penetration.

Additional aspects will be set forth in part in the description which follows and, in part, will be apparent from the description, or may be learned by practice of the presented embodiments.

According to an aspect of the disclosure, a method of manufacturing a display module of a display apparatus, includes: forming a sacrificial layer on a base substrate; forming a color filter on the sacrificial layer; forming a color layer by positioning quantum dots on the color filter; adhering to the color layer a light source substrate on which an inorganic light-emitting device is positioned so that the inorganic light-emitting device faces the color layer; and separating the base substrate from the color layer by irradiating the sacrificial layer with laser light.

The method may further include positioning a surface film on the sacrificial layer before forming the color filter on the sacrificial layer, and the forming the color layer may include forming the color filter on the surface film.

The forming the color layer may further include forming an optical diffusion layer on the color filter, wherein the optical diffusion layer may include the quantum dots.

The method may further include forming a sealing layer on the surface film before forming the optical diffusion layer on the surface film.

The forming the color layer may further include positioning the quantum dots on the sealing layer after forming the sealing layer on the surface film.

The sealing layer may be a first sealing layer, and the method may further include forming a second sealing layer on the color layer.

The forming the color layer may further include forming a black matrix on the first sealing layer before positioning the quantum dots on the first sealing layer.

The forming the color layer may further include forming the color filter in a plurality of spaces formed between the black matrix before positioning the quantum dots on the first sealing layer and after forming the black matrix on the first sealing layer.

The forming of the color layer may further include forming a plurality of position guides on the black matrix to guide a position of the color filter before positioning the quantum dots on the color filter and after forming the color filter in the plurality of spaces between the black matrix, and the color filter may be positioned between the plurality of position guides.

The method may further include adhering the light source substrate to the second sealing layer.

The separating the base substrate from the color layer may include separating the base substrate from the color layer by using Laser Lift Off.

A wavelength of the laser light may range from 200 nm to 350 nm.

The sacrificial layer may include at least one of hydrogenated amorphous silicon, amorphous gallium oxide, amorphous gallium oxinitride, and lead zirconate titanate, and a thickness of the sacrificial layer may range from 50 nm to 200 nm.

A thickness of the surface film may be less than or equal to 100 micrometers.

Each of the first sealing layer and the second sealing layer may include at least one of silica, silicon dioxide, silicon nitride or silicon oxide-nitride.

According to an aspect of the disclosure, a method of manufacturing a display module of a display apparatus, includes: forming a sacrificial layer on a base substrate; forming a black matrix on the sacrificial layer, wherein the black matrix defines a first plurality of spaces; forming a color filter on the sacrificial layer in the first plurality of spaces; forming a color layer on the color filter; adhering to the color layer a light source substrate on which an inorganic light-emitting device is positioned so that the inorganic light-emitting device faces the color layer; and separating the base substrate from the color layer by radiating laser light onto the sacrificial layer.

The forming the color layer on the color filter may further include: forming a plurality of position guides on the black matrix, wherein a second plurality of spaces are formed between the plurality of position guides, and wherein the second plurality of spaces align with the first plurality of spaces; and forming an optical diffusion layer on the color filter in the second plurality of spaces.

The optical diffusion layer may include quantum dots formed on the color filter in the second plurality of spaces.

The forming the color filter may further include forming a surface film on the color filter, and the color layer may be formed on the surface film.

According to an aspect of the disclosure, a method of manufacturing a display module of a display apparatus, includes: forming a sacrificial layer on a base substrate; forming a black matrix on the sacrificial layer, wherein the black matrix defines a first plurality of spaces; forming a color filter on the sacrificial layer in the first plurality of spaces; forming a surface film on the color filter; forming a color layer on the surface film by positioning quantum dots on the surface film, wherein the quantum dots align with the color filter; adhering to the color layer a light source substrate on which an inorganic light-emitting device is positioned so that the inorganic light-emitting device faces the color layer; and separating the base substrate from the color layer by radiating laser light onto the sacrificial layer.

### BRIEF DESCRIPTION OF THE DRAWINGS

The above and/or other aspects, features, and advantages of certain embodiment of the present disclosure will become more apparent from the following description taken in conjunction with the accompanying drawings, in which:

FIG. 1 is a perspective view of a display apparatus according to an embodiment of the disclosure;

FIG. 2 is an exploded perspective view showing main components of a display apparatus according to an embodiment of the disclosure;

FIG. 3 is a rear perspective view of a display module of a display apparatus according to an embodiment of the disclosure;

FIG. 4 is a perspective view showing some components of a display module in a display apparatus according to an embodiment of the disclosure;

FIG. 5 is an enlarged cross-sectional view showing some components of a display module in a display apparatus according to an embodiment of the disclosure;

FIG. 6 is an enlarged cross-sectional view showing some components of a display module in a display apparatus according to an embodiment of the disclosure;

FIG. 7 is an enlarged cross-sectional view showing some components of a display module in a display apparatus according to an embodiment of the disclosure;

FIG. 8 is a flowchart illustrating a process of manufacturing a display module in a display apparatus according to an embodiment of the disclosure;

FIG. 9 is a flowchart illustrating a process of manufacturing a color layer of a display module in a display apparatus according to an embodiment of the disclosure;

FIG. 10 is a schematic view illustrating a process of manufacturing a display module in a display apparatus according to an embodiment of the disclosure;

FIG. 11 is a schematic view illustrating a process of manufacturing a display module in a display apparatus according to an embodiment of the disclosure;

FIG. 12 is a schematic view illustrating a process of manufacturing a display module in a display apparatus according to an embodiment of the disclosure;

FIG. 13 is a schematic view illustrating a process of manufacturing a display module in a display apparatus according to an embodiment of the disclosure;

FIG. 14 is a schematic view illustrating a process of manufacturing a display module in a display apparatus according to an embodiment of the disclosure;

FIG. 15 is a schematic view illustrating a process of manufacturing a display module in a display apparatus according to an embodiment of the disclosure;

FIG. 16 is a schematic view illustrating a process of manufacturing a display module in a display apparatus according to an embodiment of the disclosure;

FIG. 17 is a schematic view illustrating a process of manufacturing a display module in a display apparatus according to an embodiment of the disclosure;

FIG. 18 is a schematic view illustrating a process of manufacturing a display module in a display apparatus according to an embodiment of the disclosure;

FIG. 19 is a cross-sectional view of a display apparatus according to an embodiment of the disclosure;

FIG. 20 is a flowchart illustrating a process of manufacturing a display module in a display apparatus according to an embodiment of the disclosure;

FIG. 21 is a schematic view illustrating a process of manufacturing a display module in a display apparatus according to an embodiment of the disclosure;

FIG. 22 is a schematic view illustrating a process of manufacturing a display module in a display apparatus according to an embodiment of the disclosure;

FIG. 23 is a schematic view illustrating a process of manufacturing a display module in a display apparatus according to an embodiment of the disclosure;

FIG. 24 is a flowchart illustrating a process of manufacturing a display module in a display apparatus according to an embodiment of the disclosure;

FIG. 25 is a schematic view illustrating a process of manufacturing a display module in a display apparatus according to an embodiment of the disclosure;

FIG. 26 is a schematic view illustrating a process of manufacturing a display module in a display apparatus according to an embodiment of the disclosure;

FIG. 27 is a schematic view illustrating a process of manufacturing a display module in a display apparatus according to an embodiment of the disclosure;

FIG. 28 is a schematic view illustrating a process of manufacturing a display module in a display apparatus according to an embodiment of the disclosure;

FIG. 29 is a schematic view illustrating a process of manufacturing a display module in a display apparatus according to an embodiment of the disclosure;

FIG. 30 is a schematic view illustrating a process of manufacturing a display module in a display apparatus according to an embodiment of the disclosure; and

FIG. 31 is a cross-sectional view of a display apparatus according to an embodiment of the disclosure.

### DETAILED DESCRIPTION

Configurations illustrated in the drawings and the embodiments described in the disclosure are only examples, and thus it is to be understood that various modified examples, which may replace the embodiments and the drawings of the disclosure, are possible when filing the present application.

Like reference numerals or symbols in the drawings of the disclosure denote members or components that perform the substantially same functions.

Also, the terms used in the disclosure are merely used to describe the embodiments, and are not intended to limit and/or restrict the disclosure. An expression used in the singular encompasses the expression of the plural, unless it has a clearly different meaning in the context. In the disclosure, it is to be understood that the terms such as “comprising”, “including” or “having”, etc., are intended to indicate the existence of the features, numbers, steps, operations, components, parts, or combinations thereof disclosed in the specification, and are not intended to preclude the possibility that one or more other features, numbers, steps, operations, components, parts, or combinations thereof may exist or may be added.

Also, in the disclosure, phrases, such as “A or B”, “at least one of A and B”, “at least one of A or B,” “A, B or C,” “at least one of A, B and C,” and “at least one of A, B, or C”, may include any one or all possible combinations of items listed together in the corresponding phrase among the phrases.

As used herein, the term “and/or” includes any and all combinations of one or more of a plurality of associated listed items.

Also, it will be understood that, although the terms including ordinal numbers, such as “first”, “second”, etc., may be used herein to describe various components, these components should not be limited by these terms. These terms are only used to distinguish one component from another. For example, a first component could be termed a second component, and, similarly, a second component could be termed a first component, without departing from the scope of the disclosure.

Also, in the disclosure, the meaning of “identical” may include similar in attribute or similar within a certain range. Also, the term “identical” means “substantially identical”. The meaning of “substantially identical” should be understood that a value falling within the margin of error in manufacturing or a value corresponding to a difference within a meaningless range with respect to a reference value is included in the range of “identical”.

In the following description, the terms “front”, “rear”, “left”, and “right” are defined based on the drawings, and the shapes and positions of the components are not limited by the terms.

Hereinafter, embodiments of the disclosure will be described in detail with reference to the accompanying drawings.

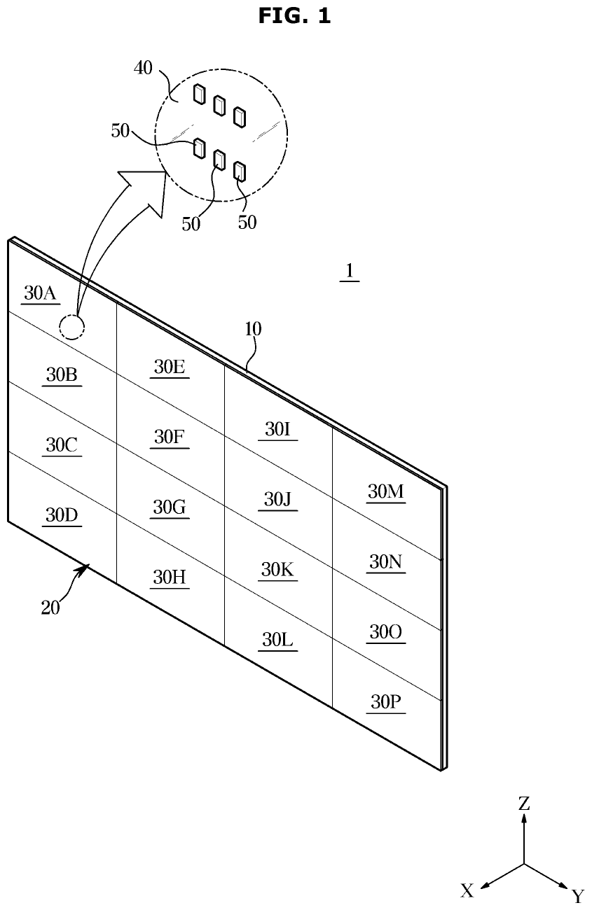

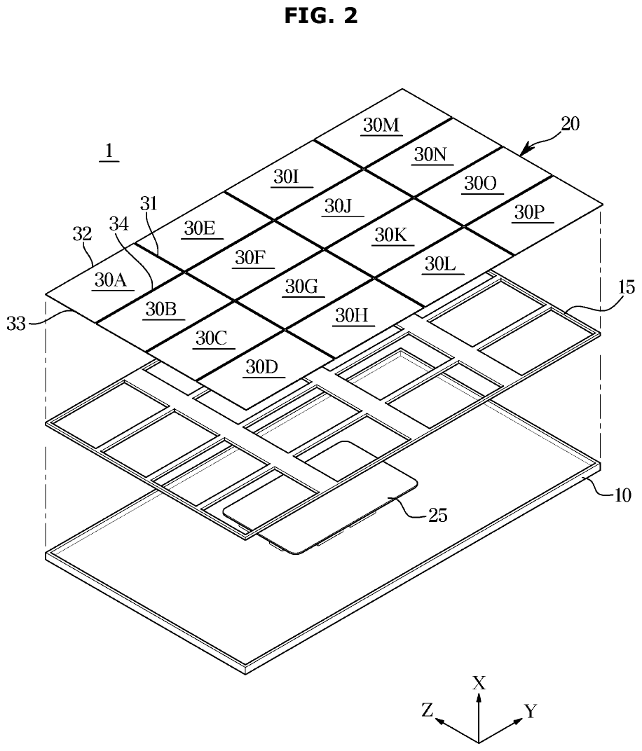

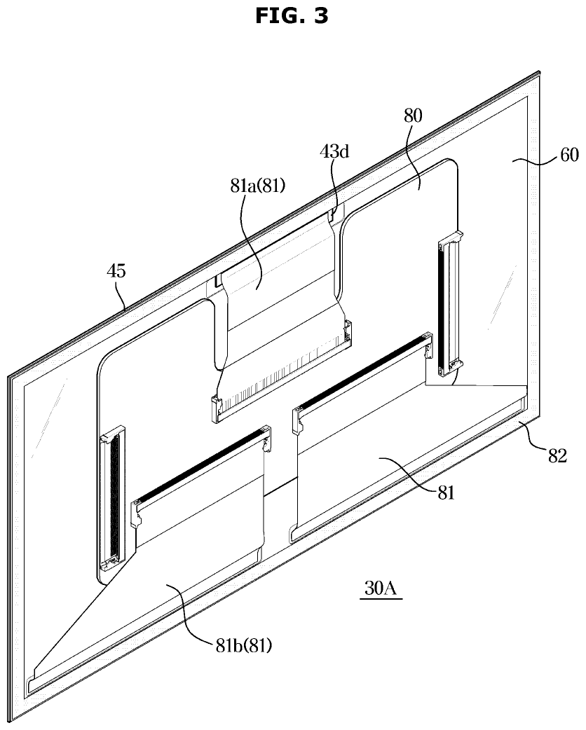

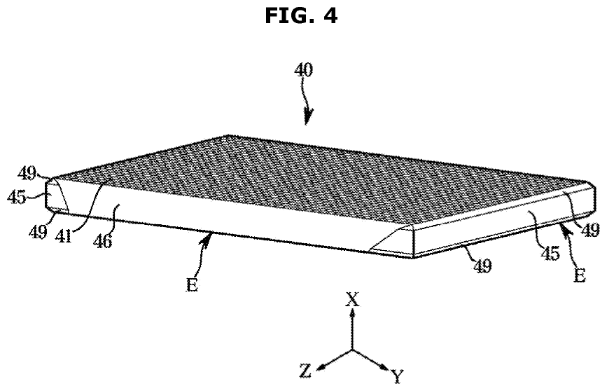

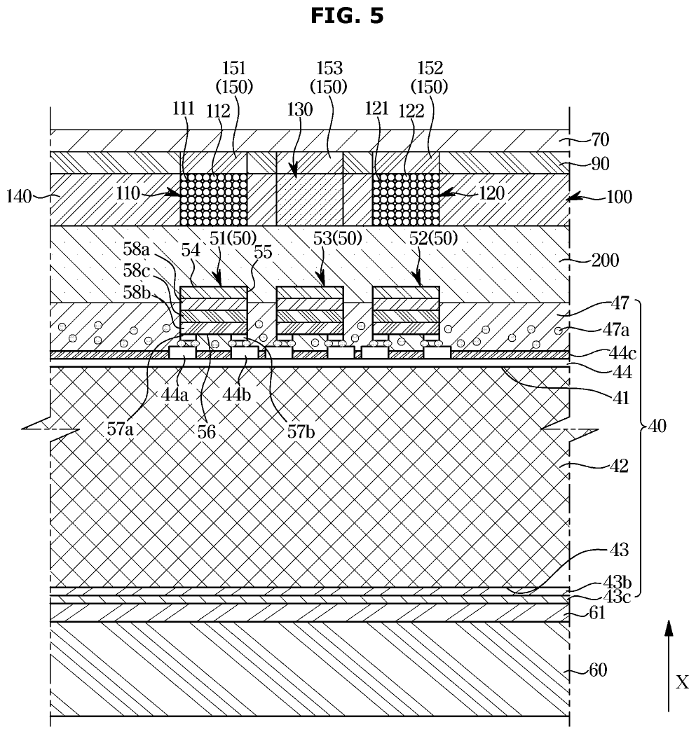

FIG. 1 is a perspective view of a display apparatus according to an embodiment of the disclosure. FIG. 2 is an exploded perspective view showing main components of a display apparatus according to an embodiment of the disclosure. FIG. 3 is a rear perspective view of a display module of a display apparatus according to an embodiment of the disclosure. FIG. 4 is a perspective view showing some components of a display module in a display apparatus according to an embodiment of the disclosure. FIG. 5 is an enlarged cross-sectional view showing some components of a display module in a display apparatus according to an embodiment of the disclosure.

Some components of a display apparatus 1, including a plurality of inorganic light-emitting devices 50 shown in the drawings may be micro-scale components having sizes of several micrometers (μm) to several hundreds of micrometers (μm), and some components (for example, the plurality of inorganic light-emitting devices 50, etc.) are shown with exaggerated sizes for convenience of description.

The display apparatus 1 may be an apparatus for displaying information and data as characters, figures, graphs, images, etc., and the display apparatus 1 may be a television (TV), a personal computer (PC), a mobile device, a digital signage, etc.

Referring to FIGS. 1 and 2, according to an embodiment of the disclosure, the display apparatus 1 may include a display panel 20 for displaying images, a power supply for supplying power to the display panel 20, a main board 25 for controlling overall operations of the display panel 20, a frame 15 supporting the display panel 20, and a rear cover 10 covering a rear side of the frame 15.

The display panel 20 may include a plurality of display modules 30A to 30P, a driving board for driving the display modules 30A to 30P, and a timing controller (TCON) board for generating timing signals required for controlling the respective display modules 30A to 30P.

The rear cover 10 may support the display panel 20. The rear cover 10 may be placed above a floor through a stand, or mounted on a wall through a hanger, etc.

The plurality of display modules 30A to 30P may be arranged in up, down, left, and right directions in such a way as to be adjacent to each other. The plurality of display modules 30A to 30P may be arranged in a matrix type of M*N. In the current embodiment, 16 display modules 30A to 30P may be provided and arranged in a matrix type of 4*4. However, a number and arrangement of the plurality of display modules 30A to 30P are not limited to these.

The plurality of display modules 30A to 30P may be mounted on the frame 15. The plurality of display modules 30A to 30P may be mounted on the frame 15 by various known methods, such as a magnetic force by a magnet, a mechanical fixing structure, etc. The rear cover 10 may be coupled to a rear side of the frame 15, and the rear cover 10 may form a rear outer appearance of the display apparatus 1.

The rear cover 10 may include a metal material. Accordingly, heat generated from the plurality of display modules 30A to 30P and the frame 15 may be efficiently conducted to the rear cover 10, resulting in improvement of heat dissipation performance of the display apparatus 1.

In this way, the display apparatus 1 according to an embodiment of the disclosure may implement a large screen by tiling the plurality of display modules 30A to 30P.

Unlike the embodiment of the disclosure, each of the plurality of display modules 30A to 30P may be applied to a display apparatus. For example, each of the display modules 30A to 30P may be installed in various electronic products or electric devices, such as wearable devices, portable devices, and handheld devices, requiring displays, and as in the embodiment of the disclosure, the plurality of display modules 30A to 30P may be assembled and arranged in a matrix type to be applied to display apparatuses, such as PC monitors, high-resolution TVs, signage, and electronic displays.

The plurality of display modules 30A to 30P may have the same configuration. Accordingly, the following description about a display module may be applied in the same way to all the other display modules.

Hereinafter, because the plurality of display modules 30A to 30P have the same configuration, the plurality of display modules 30A to 30P will be described based on a first display module 30A.

For example, to avoid redundant descriptions, main components of each of the plurality of display modules 30A to 30P will be described to be a display module 30, a substrate 40, and a surface film 70.

Also, the first display module 30A among the plurality of display modules 30A to 30P and a second display module 30E positioned adjacent to the first display module 30A in a second direction Y or a third display module 30B positioned adjacent to the first display module 30A in a third direction Z will be described as necessary.

As an example, the first display module 30A among the plurality of display modules 30A to 30P may be a quadrangle type. However, the first display module 30A may be a rectangle type or a square type.

Accordingly, the first display module 30A may include edges 31, 32, 33, and 34 formed in upper, lower, left, and right directions with respect to a first direction X which is a front direction.

For example, a left-right direction of the display apparatus 1, which is orthogonal to the first direction X being toward the front direction of the display apparatus 1, is referred to as the second direction Y, and an up-down direction of the display apparatus 1, which is orthogonal to the first direction X and the second direction Y, is referred to as the third direction Z.

Referring to FIGS. 3 and 4, a side wiring 46 may extend along the third direction Z toward a rear surface 43 of the substrate 40 via a chamfer portion 49 and a side surface 45 of the substrate 40 positioned in the third direction Z, although not limited thereto.

However, the side wiring 46 may extend along the second direction Y toward the rear surface 43 of the substrate 40 via the chamfer portion 49 and the side surface 45 of the substrate 40 positioned in the second direction Y.

According to an embodiment of the disclosure, the side wiring 46 may extend along edges E of the substrate 40, corresponding to an upper edge 32 and a lower edge 34 of the first display module 30A, although not limited thereto.

However, the side wiring 46 may extend along edges E of the substrate 40, corresponding to at least two edges among the four edges 31, 32, 33, and 34 of the first display module 30A.

An upper wiring layer may be connected to the side wiring 46 by an upper connection pad formed at the edges E of the substrate 40.

The side wiring 46 may extend along the side surface 45 of the substrate 40 and be connected to a rear wiring layer 43b formed on the rear surface 43.

An insulating layer 43c covering the rear wiring layer 43b may be formed on the rear wiring layer 43b in a direction in which the rear surface of the substrate 40 faces.

The display apparatus 1 may include the plurality of inorganic light-emitting devices 50. The plurality of inorganic light-emitting devices 50 may be electrically connected to the upper wiring layer, the side wiring 46, and the rear wiring layer 43b sequentially.

Also, the first display module 30A may include a driving circuit board 80 for electrically controlling the plurality of inorganic light-emitting devices 50 mounted on a mounting surface 41. The driving circuit board 80 may be a printed circuit board. The driving circuit board 80 may be positioned on the rear surface 43 of the substrate 40 in the first direction X. The driving circuit board 80 may be positioned on a metal plate 60 adhered on the rear surface 43 of the substrate 40.

The first display module 30A may include a flexible film 81 connecting the driving circuit board 80 to the rear wiring layer 43b to electrically connect the driving circuit board 80 to the plurality of inorganic light-emitting devices 50.

More specifically, one end of the flexible film 81 may be positioned on the rear surface 43 of the substrate 40 and connected to a rear connection pad 43d electrically connected to the plurality of inorganic light-emitting devices 50.

The rear connection pad 43d may be electrically connected to the rear wiring layer 43b. Accordingly, the rear connection pad 43d may electrically connect the rear wiring layer 43b to the flexible film 81.

Because the flexible film 81 is electrically connected to the rear connection pad 43d, the flexible film 81 may transfer power and electrical signals from the driving circuit board 80 to the plurality of inorganic light-emitting devices 50.

The flexible film 81 may be formed as a Flexible Flat cable (FFC), a Chip On Film (COF), etc.

The flexible film 81 may include a first flexible film 81a and a second flexible film 81b positioned in upper and lower directions with respect to the first direction X that is the front direction.

However, the first flexible film 81a and the second flexible film 81b may be positioned in left and right directions with respect to the first direction X or in at least two directions of the upper, lower, left, and right directions.

A plurality of second flexible films 81b may be provided, although not limited thereto. However, a single second flexible film 81b may be provided and a plurality of first flexible films 81a may be provided.

The first flexible film 81a may transfer a data signal from the driving circuit board 80 to the substrate 40. The first flexible film 81a may be a COF.

The second flexible film 81b may transfer power from the driving circuit board 80 to the substrate 40. The second flexible film 81b may be a FFC.

However, the first flexible film 81a and the second flexible film 81b may be formed in reverse.

The driving circuit board 80 may be electrically connected to a main board 25 (see FIG. 2). The main board 25 may be positioned behind the frame 15, and the main board 25 may be connected to the driving circuit board 80 through a cable behind the frame 15.

The metal plate 60 may be in contact with the substrate 40. The metal plate 60 may be adhered to the substrate 40 by a rear adhesive tape 61 positioned between the rear surface 43 of the substrate 40 and the metal plate 60 (see FIG. 5).

The metal plate 60 may be formed of a metal material having high heat conductivity. For example, the metal plate 60 may be formed of an aluminum material.

Heat generated from a thin film transistor (TFT) layer 44 and the plurality of inorganic light-emitting devices 50 mounted on the substrate 40 may be transferred to the metal pate 60 through the rear adhesive tape 61 along the rear surface 43 of the substrate 40.

Accordingly, heat generated from the substrate 40 may be efficiently transferred to the metal plate 60, and temperature of the substrate 40 may be prevented from rising above a certain temperature.

The plurality of display modules 30A to 30P may be positioned respectively at various locations in a matrix type of M*N. The display modules 30A to 30P may be independently movable. In this case, each of the display modules 30A to 30P may include the metal plate 60 to maintain a certain level of heat dissipation performance regardless of a location of the display module.

The plurality of display modules 30A to 30P may be arranged in various matrix types of M*N to form various sizes of screens of the display apparatus 1. Accordingly, heat dissipation of each of the display modules 30A to 30P by including a plurality of metal plates 60 respectively in the display modules 30A to 30P, according to an embodiment of the disclosure may improve total heat dissipation performance of the display apparatus 1, compared to heat dissipation through a single metal plate provided for temporary heat dissipation.

Upon positioning of a single metal plate inside the display apparatus 1, some portion of the metal plate may be not positioned at locations corresponding to locations where some display modules are positioned, and some portion of the metal plate may be positioned at a location where no display module is positioned, in a front-rear direction. In this case, heat dissipation efficiency of the display apparatus 1 may deteriorate.

Because the metal plate 60 is positioned at each of the display modules 30A to 30P, all the display modules 30A to 30P may themselves dissipate heat by the metal plate 60 regardless of locations of the display modules 30A to 30P, which improves the total heat dissipation performance of the display apparatus 1.

The metal plate 60 may be provided in a quadrangle type substantially corresponding to a shape of the substrate 40.

The substrate 40 may have an area that is at least equal to or larger than that of the metal plate 60. The substrate 40 and the metal plate 60 may be positioned side by side in the first direction X. In this case, four edges of the substrate 40 being a rectangle type may correspond to four edges of the metal plate 60 with respect to a center of the substrate 40 and the metal plate 60, or the four edges of the substrate 40 may be positioned outward from the four edges of the metal plate 60 with respect to the center of the substrate 40 and the metal plate 60.

The four edges E of the substrate 40 may be positioned outward from the four edges of the metal plate 60. For example, the area of the substrate 40 may be larger than that of the metal plate 60.

As a result of heat transfer to each of the display modules 30A to 30P, the substrate 40 and the metal plate 60 may be thermally expanded. However, because the metal plate 60 has a greater thermal expansion rate than the substrate 40, an expansion value of the metal plate 60 may be greater than that of the substrate 40.

In this case, in a case in which the four edges E of the substrate 40 correspond to the four edges of the metal plate 60 or are positioned inward from the four edges of the metal plate 60, the edges of the metal plate 60 may protrude outward from the substrate 40.

Accordingly, gaps between the display modules 30A to 30P may become irregular due to the thermal expansion of the metal plate 60 of each of the display modules 30A to 30P, and thus, visibility of some seams may rise, resulting in deterioration of a sense of unity of a screen of the display panel 20.

However, in the case in which the four edges E of the substrate 40 are positioned outward from the four edges of the metal plate 60, the metal plate 60 may not protrude outward from the four edges E of the substrate 40 although the substrate 40 and the metal plate 60 are thermally expanded, and accordingly, the display modules 30A to 30P may be maintained with constant gaps.

In addition, to maintain the display modules 30A to 30P at constant gaps, a front side of the frame 15 supporting the display modules 30A to 30P may have a similar material property to that of the substrate 40. For example, the display modules 30A to 30P may be adhered to the front side of the frame 15.

According to an embodiment of the disclosure, the area of the substrate 40 may substantially correspond to that of the metal plate 60. Accordingly, heat generated from the substrate 40 may be uniformly dissipated through the entire area of the substrate 40 without being isolated at some areas.

The metal plate 60 may be adhered to the rear surface 43 of the substrate 40 by the rear adhesive tape 61.

The rear adhesive tape 61 may be provided with a size corresponding to the metal plate 60. For example, an area of the rear adhesive tape 61 may correspond to that of the metal plate 60. The metal plate 60 may be substantially a quadrangle type, and the rear adhesive tape 61 may also be a quadrangle type correspondingly.

Edges of the rear adhesive tape 61 may correspond to the edges of the metal plate 60 being a rectangle type with respect to a center of the metal plate 60 and the rear adhesive tape 61.

Accordingly, the metal plate 60 and the rear adhesive tape 61 may be easily manufactured as a coupled component, which contributes to an increase of manufacturing efficiency of the display apparatus 1.

For example, by adhering the rear adhesive tape 61 to a metal plate and then cutting the metal plate and the rear adhesive tape 61 together into preset units, a number of processes may be reduced.

Heat generated from the substrate 40 may be transferred to the metal plate 60 through the rear adhesive tape 61. Accordingly, the rear adhesive tape 61 may adhere the metal plate 60 to the substrate 40 and transfer heat generated from the substrate 40 to the metal plate 60.

Accordingly, the rear adhesive tape 61 may include a material having high heat dissipation performance.

Basically, the rear adhesive tape 61 may include an adhesive material to adhere the substrate 40 to the metal plate 60.

Additionally, the rear adhesive tape 61 may include a material having high heat dissipation performance, rather than a normal adhesive material. Accordingly, the rear adhesive tape 61 may efficiently transfer heat between the substrate 40 and the metal plate 60.

Also, the adhesive material of the rear adhesive tape 61 may be a material having higher heat dissipation performance than an adhesive material forming a normal adhesive.

The material having higher heat dissipation performance may be a material capable of effectively transferring heat due to high heat conductivity, high heat transfer performance, and low specific heat.

For example, the rear adhesive tape 61 may include a graphite material, although not limited thereto. However, the rear adhesive tape 61 may be a normal material having high heat dissipation performance.

The rear adhesive tape 61 may have higher flexibility than those of the substrate 40 and the metal plate 60. Accordingly, the rear adhesive tape 61 may be formed of a material having adhesiveness, heat dissipation performance, and high flexibility. The rear adhesive tape 61 may be a baseless double-sided tape. As described above, because the rear adhesive tape 61 is a baseless tape, the rear adhesive tape 61 may be a single layer without any base positioned between one side adhered to the substrate 40 and another side adhered to the metal plate 60 to support the both sides.

Because the rear adhesive tape 61 includes no base, the rear adhesive tape 61 may not include any material that may interrupt heat transfer, and accordingly, heat dissipation performance may be improved. However, the rear adhesive tape 61 is not limited to a baseless double-sided tape, and may be a heat dissipation tape having higher heat dissipation performance than a normal double-sided tape.

To absorb any external force transferred from the substrate 40 and the metal plate 60, the rear adhesive tape 61 may be formed of a material having high flexibility. More specifically, the flexibility of the rear adhesive tape 61 may be higher than those of the substrate 40 and the metal plate 60.

Accordingly, although heat is transferred to the substrate 40 and the metal plate 60 and thus, an external force generated by changes in size of the substrate 40 and the metal plate 60 is transferred to the rear adhesive tape 61, the rear adhesive tape 61 may itself be deformed to prevent the external force from being transferred to other components.

The rear adhesive tape 61 may have a preset thickness in the first direction X. Upon thermal expansion of the metal plate 60 due to heat transferred to the metal plate 60 or contraction of the metal plate 60 cooled, the metal plate 60 may be expanded or contracted in the first direction X and directions that are orthogonal to the first direction X, and accordingly, an external force may be transferred to the substrate 40.

Because the metal plate 60 is formed with a size corresponding to the substrate 40 and covers the entire rear surface 43 of the substrate 40, as described above, a fixing member 82 may be positioned on a rear surface of the metal plate 60, although not limited thereto.

However, the fixing member 82 may be positioned on the rear surface 43 of the substrate 40. In this case, the substrate 40 may be adhered directly to the frame 15 through the fixing member 82.

Unlike an embodiment of the disclosure, the metal plate 60 may cover only an area of the rear surface 43 of the substrate 40, and the fixing member 82 may be adhered to another area of the rear surface 43 of the substrate 40, not covered by the metal plate 60.

The fixing member 82 may be, for example, a double-sided tape.

Referring to FIG. 5, each of the plurality of display modules 30A to 30P may include the substrate 40 and the plurality of inorganic light-emitting devices 50 mounted on the substrate 40. The substrate 40 may be a light source substrate 40. The plurality of inorganic light-emitting devices 50 may be mounted on the mounting surface 41 of the substrate 40 toward the first direction X. The mounting surface 41 may be a first surface. Also, the mounting surface 41 may be a first side of the substrate 40, and the metal plate 60 may be positioned on a second side of the substrate 40, the second side being opposite to the first side. For convenience of description, in FIG. 5, a thickness of the substrate 40 in the first direction X is shown to be exaggeratedly great. The first direction X may be the front direction.

The substrate 40 may be a quadrangle type. Each of the plurality of display modules 30A to 30P may be a quadrangle type, as described above, and the substrate 40 may also be a quadrangle type correspondingly.

The substrate 40 may be a rectangle type or a square type.

Accordingly, for example, in the first display module 30A, the substrate 40 may include the four edges E corresponding to the edges 31, 32, 33, and 34 of the first display module 30A, formed in the upper, lower, left, and right directions with respect to the first direction X that is the front direction (see FIG. 4).

The substrate 40 may include a substrate body 42, the mounting surface 41 forming one side of the substrate body 42, the rear surface 43 forming another side of the substrate body 42 and being opposite to the mounting surface 41, and the side surface 45 positioned between the mounting surface 41 and the rear surface 43.

The side surface 45 may form a side end of the substrate 40 in the second direction Y and the third direction Z that are orthogonal to the first direction X.

The substrate 40 may include the chamfer portion 49 formed between the mounting surface 41 and the side surface 45 and between the rear surface 43 and the side surface 45.

The chamfer portion 49 may prevent substrates from colliding with each other and being broken upon arrangement of the plurality of display modules 30A to 30P.

The edges E of the substrate 40 may include the side surface 45 and the chamfer portion 49.

The substrate 40 may include the TFT layer 44 formed on the substrate body 42 to drive the inorganic light-emitting devices 50. The substrate body 42 may include a glass substrate. For example, the substrate 40 may include a COG type substrate 40. On the substrate 40, a first pad electrode 44a and a second pad electrode 44b for electrically connecting the inorganic light-emitting devices 50 to the TFT layer 44 may be formed.

TFTs constituting the TFT layer 44 are not limited to specific structures or types and may be configured as one or more embodiments. For example, TFTs of the TFT layer 44 according to an embodiment of the disclosure may be implemented as Low Temperature Poly Silicon (LTPS) TFTs, oxide TFTs, Si (poly silicon or a-silicon) TFTs, organic TFTs, graphene TFTs, etc.

Also, according to the substrate body 42 of the substrate 40, provided as a silicon wafer, the TFT layer 44 may be replaced with a Complementary Metal-Oxide Semiconductor (CMOS) type, a n-type Metal-Oxide Semiconductor Field Effect Transistor (MOSFET), or a p-type MOSFET.

The plurality of inorganic light-emitting devices 50 may be formed of an inorganic material, and may include inorganic light-emitting devices having sizes of several micrometers (μm) to tens of micrometers (μm) in width, length, and height, respectively. A micro inorganic light-emitting device may have a shorter side length of 100 micrometers (μm) or less in width, length, and height. For example, the inorganic light-emitting devices 50 may be picked up from a sapphire or silicon wafer and then transferred directly onto the substrate 40. The plurality of inorganic light-emitting devices 50 may be picked up and conveyed through an electrostatic method using an electrostatic head or a stamp method using an elastic polymer material, such as polydimethylsiloxane (PDMS) or silicon, as a head.

The plurality of inorganic light-emitting devices 50 may be a light-emitting structure including an n-type semiconductor 58a, an active layer 58c, a p-type semiconductor 58b, a first contact electrode 57a, and a second contact electrode 57b.

Any one of the first contact electrode 57a and the second contact electrode 57b may be electrically connected to the n-type semiconductor 58a, and another one may be electrically connected to the p-type semiconductor 58b.

The first contact electrode 57a and the second contact electrode 57b may be a flip chip type arranged horizontally toward the same direction (an opposite direction of a light-emitting direction).

Each inorganic light-emitting device 50 may include a light-emitting surface 54 positioned toward the first direction X upon being mounted on the mounting surface 41, a side surface 55, and a bottom surface 56 being opposite to the light-emitting surface 54, wherein the first contact electrode 57a and the second contact electrode 57b may be formed on the bottom surface 56.

For example, the first and second contact electrodes 57a and 57b of the inorganic light-emitting device 50 may be opposite to the light-emitting surface 54, and accordingly, the first and second contact electrodes 57a and 57b may be positioned in the opposite direction of the light-emitting direction.

The first and second contact electrodes 57a and 57b may face the mounting surface 41, and be electrically connected to the TFT layer 44. Also, the light-emitting surface 54 through which light is radiated may be positioned in an opposite direction of the direction in which the first and second contact electrodes 57a and 57b are positioned.

Accordingly, light generated by the active layer 58c may be radiated toward the first direction X through the light-emitting surface 54, without any interference by the first and second contact electrodes 57a and 57b.

For example, the first direction X may be defined as a direction in which the light-emitting surface 54 is positioned to radiate light.

The first contact electrode 57a and the second contact electrode 57b may be electrically connected respectively to the first pad electrode 44a and the second pad electrode 44b formed on the mounting surface 41 of the substrate 40.

The inorganic light-emitting device 50 may be connected directly to the first and second pad electrodes 44a and 44b through an anisotropic conductive layer 47 or a bonding material such as a solder.

On the substrate 40, the anisotropic conductive layer 47 may be formed to mediate an electrical connection between the first and second contact electrodes 57a and 57b and the first and second pad electrodes 44a and 44b. The anisotropic conductive layer 47 may be formed by applying an anisotropic conductive adhesive on a protective film, and have a structure in which conductive balls 47a are distributed in an adhesive resin. Each conductive ball 47a may be a conductive sphere surrounded by a thin insulating film, and as a result of breaking of the insulating film by pressure, the conductive ball 47a may electrically connect a conductor to another one.

The anisotropic conductive layer 47 may include an anisotropic conductive film (ACF) being in a form of a film, and an anisotropic conductive paste (ACP) being in a form of a paste.

In an embodiment of the disclosure, the anisotropic conductive layer 47 may be provided as an anisotropic conductive film.

Accordingly, the insulating films of the conductive balls 47a may be broken by pressure applied to the anisotropic conductive layer 47 upon mounting of the plurality of inorganic light-emitting devices 50 on the substrate 40, and as a result, the first and second contact electrodes 57a and 57b of the inorganic light-emitting devices 50 may be electrically connected to the first and second pad electrodes 44a and 44b of the substrate 40.

The plurality of inorganic light-emitting devices 50 may be mounted on the substrate 40 through a solder, instead of the anisotropic conductive layer 47. By performing a reflow process after arranging the inorganic light-emitting devices 50 on the substrate 40, the inorganic light-emitting devices 50 may be bonded on the substrate 40.

The anisotropic conductive layer 47 may be formed with a dark color. For example, the anisotropic conductive layer 47 may absorb external light such that the substrate 40 is shown to be black, thereby improving contrast of a screen. The anisotropic conductive layer 47 provided with a dark color may function to complement the light absorbing layer 44c formed on the entire mounting surface 41 of the substrate 40.

The display apparatus 1 may include the plurality of inorganic light-emitting devices 50. The plurality of inorganic light-emitting devices 50 may include a blue light-emitting device 50. For example, all of the plurality of inorganic light-emitting devices 50 may be blue inorganic light-emitting devices 50, although not limited thereto. However, the inorganic light-emitting devices 50 may be red light-emitting devices 50 and green light-emitting devices 50.

The inorganic light-emitting devices 50 may include a first inorganic light-emitting device 51, a second inorganic light-emitting device 52, and a third inorganic light-emitting device 53. The third inorganic light-emitting device 53 may be positioned between the first inorganic light-emitting device 51 and the second inorganic light-emitting device 52. However, the inorganic light-emitting devices 50 may be referred to as different names from those in the above example. For example, an inorganic light-emitting device positioned between the first inorganic light-emitting device 51 and the third inorganic light-emitting device 52 may be the second inorganic light-emitting device 53. Also, an inorganic light-emitting device positioned between the second inorganic light-emitting device 51 and the third inorganic light-emitting device 52 may be the first inorganic light-emitting device 53.

The first inorganic light-emitting device 51, the second inorganic light-emitting device 52, and the third inorganic light-emitting device 53 may be arranged at preset intervals in a line as in the embodiment of the disclosure, or may be arranged in another shape such as a triangle shape.

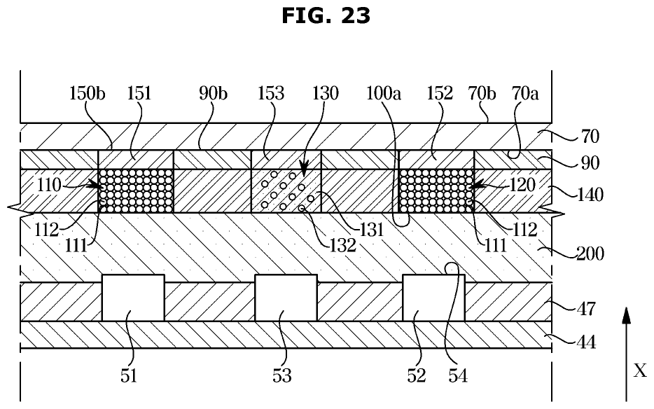

The display apparatus 1 may further include a surface film 70. The surface film 70 may be positioned to one sides of the inorganic light-emitting devices 50 to reduce glare that is caused by external light of the display apparatus 1 and/or internal reflection of the display apparatus 1. For example, the surface film 70 may be positioned in the first direction X from the inorganic light-emitting devices 50. The surface film 70 may be in contact with a color layer 100. For example, a first surface 70a of the surface film 70 may be in contact with a second surface 90b and 150b of the color layer 100 (see FIG. 23).

The surface film 70 may be formed of a transparent polymer material. For example, the surface film 70 may include at least one of a silicon resin, polymethyl methacrylate (PMMA), or PDMS.

Also, because the surface film 70 is formed of a polymer material, the surface film 70 may have a thickness of 100 micrometers (μm) or less.

The display apparatus 1 may further include the color layer 100. The color layer 100 may convert a color of light emitted from the inorganic light-emitting devices 50. The color layer 100 may be positioned between the surface film 70 and the inorganic light-emitting devices 50. For example, the color layer 100 may be positioned between the surface film 70 and an adhesive layer 200 in the first direction X. The color layer 100 may be positioned in front of the inorganic light-emitting devices 50.

The color layer 100 may include optical layers 110, 120, and 130. The optical layers 110, 120, and 130 may diffuse light emitted from the inorganic light-emitting devices 50 toward the front direction X. For example, the optical layers 110, 120, and 130 may diffuse light emitted from the inorganic light-emitting devices 50 toward the surface film 70. The optical layers 110, 120, and 130 may also be referred to as light diffusion layers 110, 120, and 130.

The color layer 100 may include a resin 111 and 121 and a color conversion material 112 and 122. The resin 111 and 121 may be mixed with the color conversion material 112 and 122. The resin 111 and 121 may be transparent. The resin 111 and 121 or a mixture of the resin 111 and 121 and the color conversion material 112 and 122 may be provided inside the optical layers 110, 120, and 130.

Light emitted from the inorganic light-emitting devices 50 may be converted in color by passing through the color conversion material 112 and 122. For example, the color conversion material 112 and 122 may include quantum dots 112 and 122. However, a kind of the color conversion material 112 and 122 is not limited to this.

The optical layers 110, 120, and 130 may include a first optical layer 110, a second optical layer 120, and a third optical layer 130. The first optical layer 110 may correspond to the first inorganic light-emitting device 51, the second optical layer 120 may correspond to the second inorganic light-emitting device 52, and the third optical layer 130 may correspond to the third inorganic light-emitting device 53.

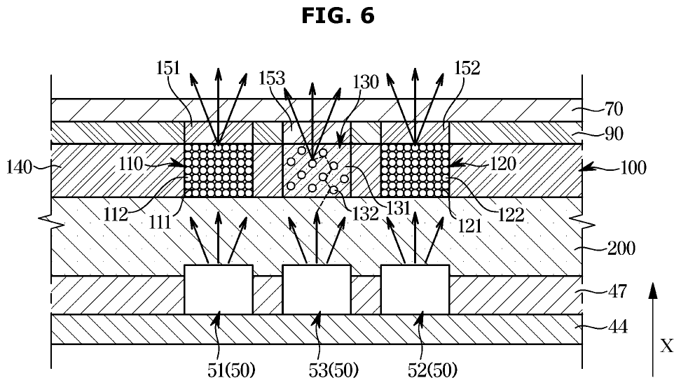

For example, light emitted from the first inorganic light-emitting device 51 may pass through the first optical layer 110. The light passed through the first optical layer 110 may be diffused and/or emitted in the front direction X (see FIG. 6). For example, the light passed through the first optical layer 110 may show a Lambertian emission pattern. The first optical layer 110 may be a first color conversion layer 110. The light passed through the first color conversion layer 110 may show a first color. For example, the inorganic light-emitting device 50 may be a blue inorganic light-emitting device. In this case, the first color may be green. For example, the first color conversion layer 110 may be a green conversion layer.

The resin 111 and the quantum dots 112 may be positioned in the first color conversion layer 110. The quantum dots 112 may be positioned in the resin 111. The quantum dots 112 positioned in the first color conversion layer 110 may convert light passing through the first color conversion layer 110 into green light. Light passing through the first color conversion layer 110 may show a color by being absorbed in the quantum dots 112 and then emitted from the quantum dots 112, and the light may be emitted in all directions. Accordingly, light passed through the first color conversion layer 110 may show the Lambertian emission pattern and be emitted toward the front direction. The quantum dots 112 in the first color conversion layer 110 may be first quantum dots 112.

Also, for example, light emitted from the second inorganic light-emitting device 52 may pass through the second optical layer 120. The light passed through the second optical layer 120 may be diffused and/or emitted toward the front direction X (see FIG. 6). For example, light passed through the second optical layer 120 may show the Lambertian emission pattern. The second optical layer 120 may be a second color conversion layer 120. Light passed through the second color conversion layer 120 may show a second color. For example, in a case in which the inorganic light-emitting device 50 is a blue inorganic light-emitting device 50, the second color may be red. For example, the second color conversion layer 120 may be a red conversion layer.

The resin 121 and the quantum dots 122 may also be positioned in the second color conversion layer 120. The quantum dots 122 may be positioned in the resin 121. The quantum dots 122 positioned in the second color conversion layer 120 may convert light passing through the second color conversion layer 120 into red light. Light passing through the second color conversion layer 120 may show a color by being absorbed in the quantum dots 122 and then emitted from the quantum dots 122, and the light may be emitted in all directions. Accordingly, light passed through the second color conversion layer 120 may show the Lambertian emission pattern and be emitted toward the front direction. The quantum dots 122 in the second color conversion layer 120 may be second quantum dots 122.

Also, for example, light emitted from the third inorganic light-emitting device 53 may pass through the third optical layer 130 (see FIG. 6). The third optical layer 130 may be a scattering layer 130. Light passed through the scattering layer 130 may be diffused and/or emitted toward the front direction. A resin may also be positioned inside the scattering layer 130. Details about the scattering layer 130 will be described below.

The color layer 100 and the inorganic light-emitting devices 50 may form a pixel. For example, the plurality of inorganic light-emitting devices 50, the first color conversion layer 110, the second color conversion layer 120, and the scattering layer 130 may form a pixel. In this case, each pair of the first inorganic light-emitting device 51 and the first color conversion layer 110, the second inorganic light-emitting device 52 and the second color conversion layer 120, and the third inorganic light-emitting device 53 and the scattering layer 130 may form a sub pixel. For example, the first inorganic light-emitting device 51 and the first color conversion layer 110 may form a green sub pixel, the second inorganic light-emitting device 52 and the second color conversion layer 120 may form a red sub pixel, and the third inorganic light-emitting device 53 and the scattering layer 130 may form a blue sub pixel.

The color layer 100 may further include a position guide 140. The position guide 140 may guide positions of the first color conversion layer 110, the second color conversion layer 120, and the scattering layer 130. The first color conversion layer 110, the second color conversion layer 120, and the scattering layer 130 may be located at correct positions by the position guide 140. The position guide 140 may guide positions of the resin 111, 121, and 131 (see FIG. 6), the quantum dots 112 and 122, and scattering particles 132 (see FIG. 6). The position guide 140 may be formed of an organic material and include a dark color. For example, the position guide 140 may have a gray color. The position guide 140 may be formed of a material having low transmissivity. For example, the position guide 140 may be formed of a material having a high light absorption rate or high reflectance. Accordingly, the position guide 140 may absorb and/or reflect light traveling toward the position guide 140 among light diffused by the first color conversion layer 110, the second color conversion layer 120, and the scattering layer 130. The position guide 140 may also be referred to as a partition wall 140.

The position guide 140 may be positioned between the surface film 70 and the inorganic light-emitting devices 50. For example, the position guide 140 may be positioned between a black matrix 90 and the adhesive layer 200 in the first direction X.

The display apparatus 1 may further include the black matrix 90. For example, the color layer 100 may include the black matrix 90. The black matrix 90 may absorb external light and improve contrast. For example, the black matrix 90 may be positioned between the position guide 140 and the surface film 70 in the first direction X. A color filter 150 may be positioned between black matrixes 90.

The display apparatus 1 may further include the color filter 150. For example, the color filter 150 may be positioned between the surface film 70 and the optical layers 110, 120, and 130 along the first direction X. The color filter 150 may be positioned between the black matrixes 90 in the second direction Y or the third direction Z.

The color filter 150 may remove noise from light emitted from the optical layers 110, 120, and 130 in the front direction. For example, the inorganic light-emitting devices 50 may be blue inorganic light-emitting devices 50, and the color filter 150 may remove light not converted by the color conversion layers 110 and 120 among blue light.

For example, the color filter 150 may include a first color filter 151, a second color filter 152, and a third color filter 153. The first color filter 151 may remove noise from light emitted from the first color conversion layer 110 toward the front direction. For example, light passed through the first color conversion layer 110 may be green light having a first wavelength showing a green color, and the first color filter 151 may remove light having other wavelengths (or a different range) than the first wavelength showing the green color. The second color filter 152 may remove noise from light emitted from the second color conversion layer 120 toward the front direction. For example, light passed through the second color conversion layer 120 may be red light having a second wavelength showing a red color, and the second color filter 152 may remove light having other wavelengths (or a different range) than the second wavelength showing the red color. The third color filter 153 may remove noise from light emitted from the scattering layer 130 toward the front direction. For example, light emitted through the inorganic light-emitting devices 50 may be green light having a third wavelength showing a blue color, and the third color filter 153 may remove light having other wavelengths (or a different range) than the third wavelength showing the blue color.

The substrate 40 may include the light absorbing layer 44c for absorbing external light and improving contrast. The light absorbing layer 44c may be formed on the entire mounting surface 41 of the substrate 40. The light absorbing layer 44c may be formed between the TFT layer 44 and the anisotropic conductive layer 47.

The plurality of display modules 30A to 30P may include the surface film 70 positioned on the mounting surface 41 in the first direction X to cover the mounting surface 41, the inorganic light-emitting devices 50 and/or the color layer 100 of the plurality of display modules 30A to 30P.

A plurality of surface films 70 may be formed respectively on the plurality of display modules 30A to 30P in the first direction X.

After the surface film 70 is positioned on each of the plurality of display modules 30A to 30P, the plurality of display modules 30A to 30P may be assembled together. In examples of the first display module 30A and the second display module 30E of the plurality of display modules 30A to 30P, a first surface film may be formed on the mounting surface 41 of the first display module 30A, and a second surface film may be formed on the mounting surface 41 of the second display module 30E.

The surface film 70 may cover the substrate 40 and protect the substrate 40 from an external force or external water.

The surface film 70 may include a plurality of layers that may be a functional film having optical performance.

The display apparatus 1 may include the adhesive layer 200 for adhering the surface film 70 to the mounting surface 41 of the substrate 40.

Also, each of the plurality of display modules 30A to 30P may include the rear adhesive tape 61 positioned between the rear surface 43 of the substrate 40 and the metal plate 60 to adhere the rear surface 43 to the metal plate 60.

The rear adhesive tape 61 may be a double-sided adhesive tape, although not limited thereto. However, the rear adhesive tape 61 may be an adhesive layer, not a tape. For example, the rear adhesive tape 61 is not limited to a tape as an example of a medium for adhering the rear surface 43 of the substrate 40 to the metal plate 60, and may be one of various kinds of mediums.

The plurality of inorganic light-emitting devices 50 may be electrically connected to a pixel driving wiring formed on the mounting surface 41 and an upper wiring layer extending through the side surface 45 of the substrate 40 and formed as a pixel driving wiring.

The upper wiring layer may be formed below the anisotropic conductive layer 47. The upper wiring layer may be electrically connected to the side wiring 46 formed on the side surface 45 of the substrate 40. The side wiring 46 may be in a form of a thin film (see FIG. 4).

FIG. 6 is an enlarged cross-sectional view showing some components of a display module in a display apparatus according to an embodiment of the disclosure. FIG. 6 is an enlarged view schematically showing some components shown in FIG. 5.

Referring to FIG. 6, in the display apparatus 1 according to an embodiment, each of the display modules 30A to 30P may include the inorganic light-emitting devices 50 and the color layer 100. Light emitted from the inorganic light-emitting devices 50 may travel toward the color layer 100.

The color layer 100 may include the scattering layer 130. The resin 131 and the scattering particles 132 may be provided inside the scattering layer 130. The resin 131 may be mixed with the scattering particles 132 inside the scattering layer 130. The scattering particles 132 may scatter light emitted from the inorganic light-emitting devices 50 toward the front direction. For example, light emitted from the third inorganic light-emitting device 50 may collide with the scattering particles 132 to form a great emission angle toward the front direction.

For example, light emitted from the inorganic light-emitting devices 50 may be absorbed in and/or reflected from the position guide 140, or for another reason, a light emission pattern may be reduced, resulting in a reduction of a viewing angle. However, light passing through the first color conversion layer 110 and the second color conversion layer 120 may be absorbed in the quantum dots 112 and 122 and then emitted in all directions. Accordingly, the light passed through the first color conversion layer 110 and the second color conversion layer 120 may show the Lambertian emission pattern to have a wide viewing angle. For example, a viewing angle of light emitted from the first inorganic light-emitting device 51 and the second inorganic light-emitting device 52 may increase.

Also, light passing through the scattering layer 130 may collide with the scattering particles 132 to improve an emission pattern of the light. For example, a part of light emitted from the third inorganic light-emitting device 53 may pass through the scattering layer 130 and another part of the light may be absorbed in and/or reflected from the position guide 140. Like the quantum dots 112 and 122 improving an emission pattern of light, the scattering particles 132 may scatter incident light. For example, the scattering particles 132 may collide with light entered the scattering layer 130 to cause the light to have a wide viewing angle toward the front direction. For example, a viewing angle of light emitted from the third inorganic light-emitting device 53 may increase. Accordingly, a user may watch the display apparatus 1 with reduced color coordination distortion depending on a viewing angle with respect to the display apparatus 1.

The scattering particles 132 may include TiO₂, ZnO, ZrO₂, and Al₂O₃. For example, a plurality of scattering particles 132 may be provided, and the respective scattering particles 132 may be formed of TiO₂, ZnO, ZrO₂, and Al₂O₃. Also, the plurality of scattering particles 132 may include at least one of TiO₂, ZnO, ZrO₂, or Al₂O₃, and also, N scattering particles 132 may be divided into N/4 each formed of TiO₂, ZnO, ZrO₂, or Al₂O₃. However, a composition of the scattering particles 132 is not limited to the above examples.

Also, each of the scattering particles 132 may have a size of 100 nm to 500 nm. However, the size of each scattering particle 132 is not limited to the above example.

Also, content of the scattering particles 132 may range from 2 wt % to 10 wt %. For example, the scattering particles 132 may be mixed with a resin, wherein (weight of scattering particles)/(weight of scattering particles+weight of resin)=2 wt % to 10 wt %. However, the content of the scattering particles 132 is not limited to the above example.

In a state in which the position guide 140 is positioned above the surface film 70, the color layer 100 including the scattering layer 130 may be manufactured. For example, the scattering layer 130 may be formed by applying a scattering particles solution obtained by mixing the resin 131 with the scattering particles 132 and then hardening the scattering particles solution. Then, the color layer 100 including the scattering layer 130 may rotate by 180 degrees and be adhered, coupled and/or attached to the inorganic light-emitting devices 50 and the anisotropic conductive layer 47 through the adhesive layer 200.

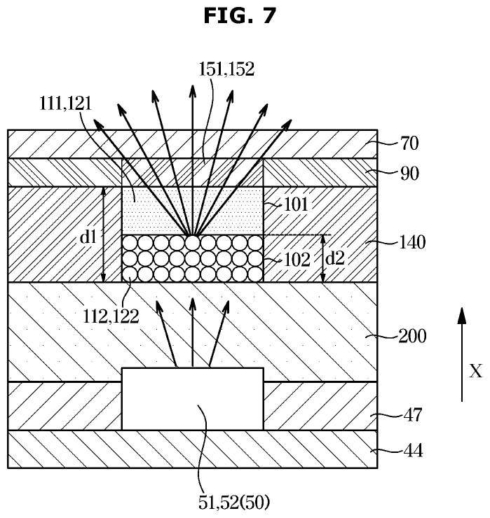

FIG. 7 is an enlarged cross-sectional view showing some components of a display module in a display apparatus according to an embodiment of the disclosure. FIG. 7 is an enlarged view schematically showing some components shown in FIG. 5.

Referring to FIG. 7, the first color conversion layer 110 and/or the second color conversion layer 120 in the display apparatus 1 according to an embodiment are shown. Or, at least one of the first color conversion layer 110 or the second color conversion layer 120 is shown.

The color filters 151, 152 may include a resin layer 101 including the resin 111 and 121 that is transparent, and a quantum dot layer 102 in which the quantum dots 112 and 122 are mixed with the resin 111 and 121.

Light emitted from the inorganic light-emitting devices 50 toward the front direction may show the Lambertian emission pattern by the quantum dots 112 and 122 by passing through the quantum dot layer 102. For example, light emitted from the first inorganic light-emitting device 51 and/or the second inorganic light-emitting device 52 may be absorbed in the quantum dots 112 and 122 and then emitted in all directions.

According to an embodiment, the quantum dot layer 102 may be formed in lower portions of the color conversion layers 110 and 120 and/or the color layer 100. A ratio of a thickness of the quantum dot layer 102 with respect to a thickness of the color conversion layers 110 and 120 and/or the color layer 100 may range from 0.2 to 1. Because the quantum dot layer 102 is positioned in the lower portions of the color conversion layers 110 and 120, a part of light again emitted from the quantum dot layer 102 may be absorbed in the position guide 140, and another part of light not absorbed in the position guide 140 may be emitted in the front direction. Accordingly, an emission angle of light emitted from the color conversion layers 110 and 120 may be reduced.

Light emitted from a red sub pixel and a green sub pixel may be less reduced in brightness than light scattered in a blue sub pixel, which causes a brightness difference to generate color coordinate distortion depending on a viewing angle.

According to an embodiment, because an emission angle of light emitted from the color conversion layers 110 and 120 is reduced, brightness differences between the sub pixels may be reduced and color coordinate distortion may be reduced.

After the surface film 70 is positioned below the color layer 100, a resin solution consisting of the resin 111 and 121 may be applied in spaces of the color conversion layers 110 and 120 of FIG. 7. Thereafter, a process of immediately hardening the resin solution may be performed. After the resin solution is hardened, a quantum dot solution in which the resin 111 and 121 is mixed with the quantum dots 112 and 122 may be additionally applied. The quantum dot solution may be applied in the color conversion layers 110 and 120 to have a smaller thickness than that of the color conversion layers 110 and 120 that are finally formed. Thereafter, a process of immediately hardening the quantum dot solution may be performed.

Then, the color layer 100 including the color conversion layers 110 and 120 may rotate by 180 degrees and be adhered, coupled and/or attached to the inorganic light-emitting devices 50 and the anisotropic conductive layer 47 through the adhesive layer 200.

The quantum dots 112 and 122 may be biased to one side within the color conversion layers 110 and 120. For example, the quantum dots 112 and 122 may be positioned adjacent to the adhesive layer 200 and/or the inorganic light-emitting devices 50. For example, the quantum dots 112 and 122 may be positioned at rear portions of the color conversion layers 110 and 120. A ratio d2/d1 of a thickness d2 of the quantum dot layer 102 in which the quantum dots 112 and 122 are positioned with respect to a thickness d1 of the color conversion layers 110 and 120 and/or the color layer 100 may range from 0.2 to 1.

In the color conversion layers 120 and 120, different kinds of structures of the quantum dot layer 102 in which the resin 111 and 121 is mixed with the quantum dots 112 and 122 and the resin layer in which only the resin 111 and 121 is positioned may be formed. The quantum dot layers 102 may be positioned at the lower portions of the color conversion layers 110 and 120.

As described above, a part of light emitted from the quantum dot layer 102 positioned at the lower portions of the color conversion layers 110 and 120 may be absorbed in the position guide 140, and another part of light not absorbed in the position guide 140 may be emitted in the front direction. Accordingly, an emission angle of light emitted from the color conversion layers 110 and 120 may be reduced. The display apparatus 1 according to an embodiment may reduce a difference between an emission angle of light emitted from the red and/or green sub pixel and an emission angle of light emitted from the blue sub pixel, thereby reducing color coordinate distortion depending on a viewing angle.

Meanwhile, by configuring red/green color filter layers with different kinds of structures of a transparent resin layer (upper portion) and a quantum dot layer (lower portion), a traveling path of converted light emitted from the quantum dot layer of the lower portion may be limited. In this way, by changing the structure of the color filters 151, 152, an emission angle of red/green emitted from the display apparatus 1 may be reduced.

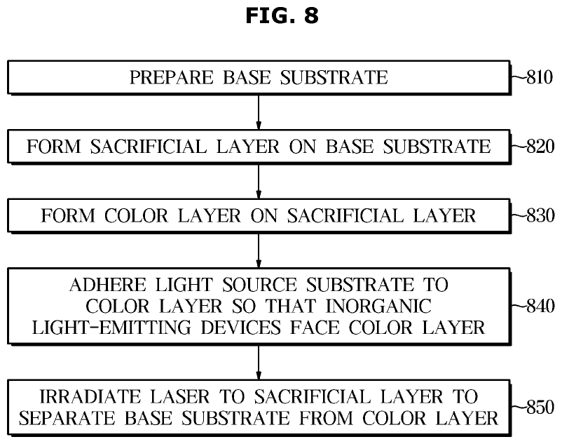

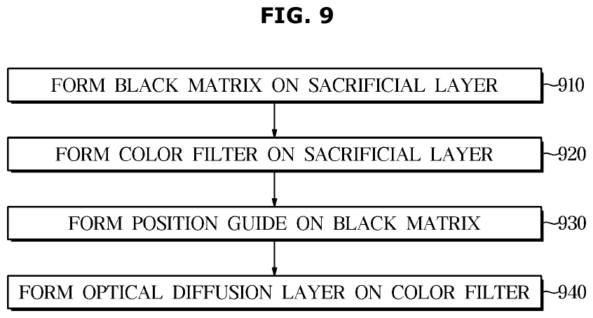

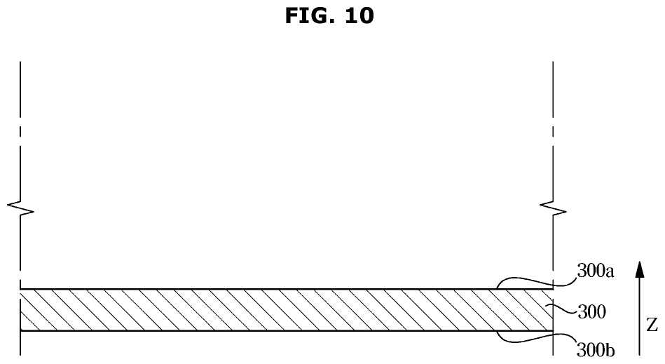

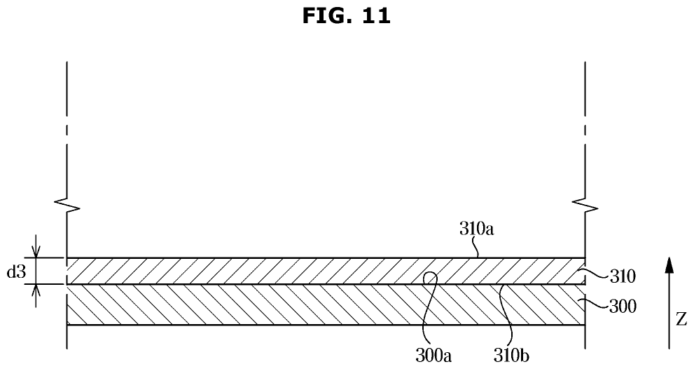

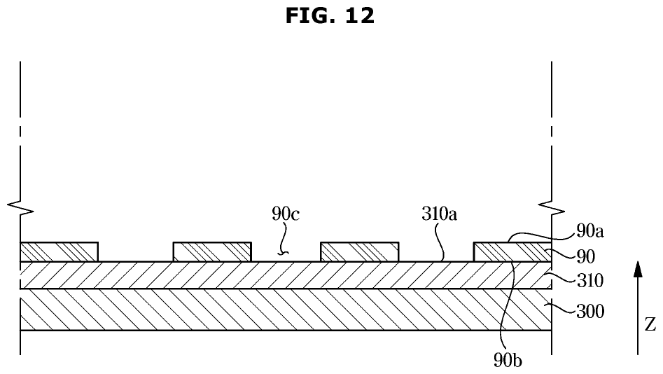

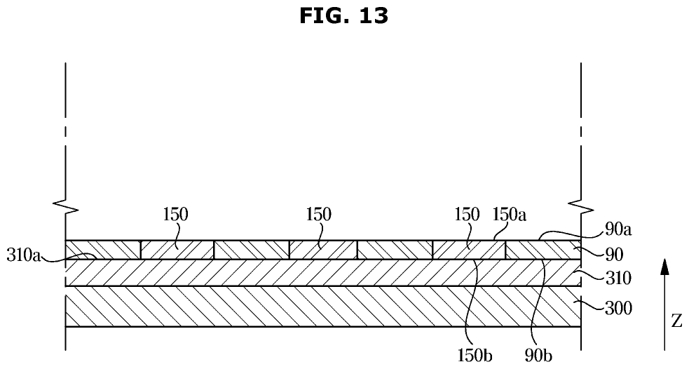

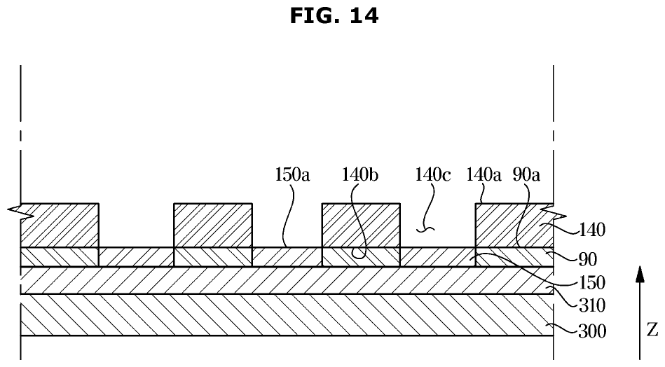

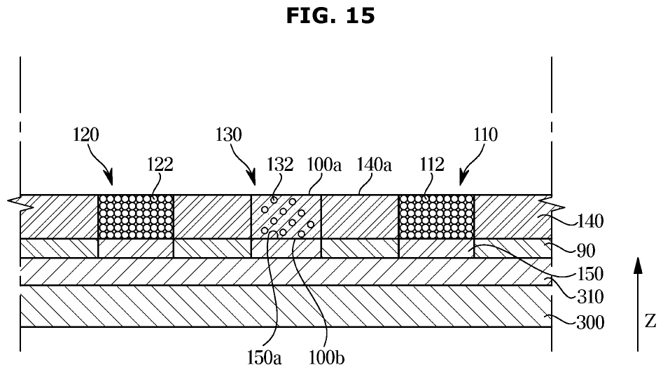

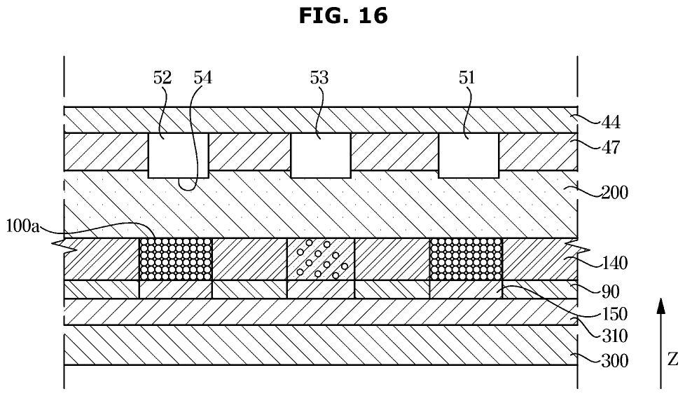

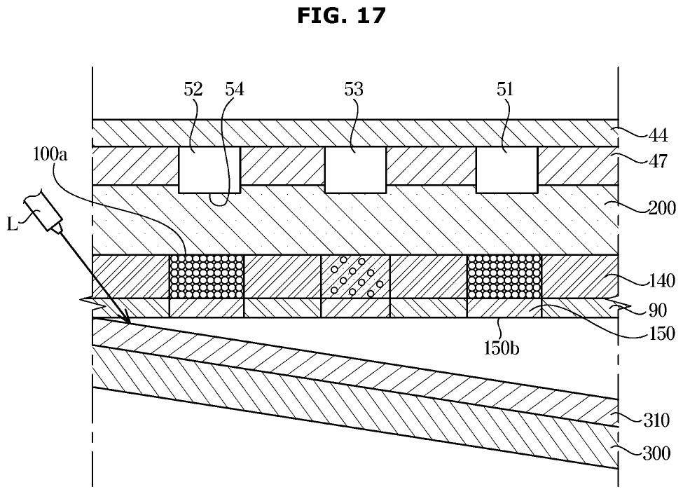

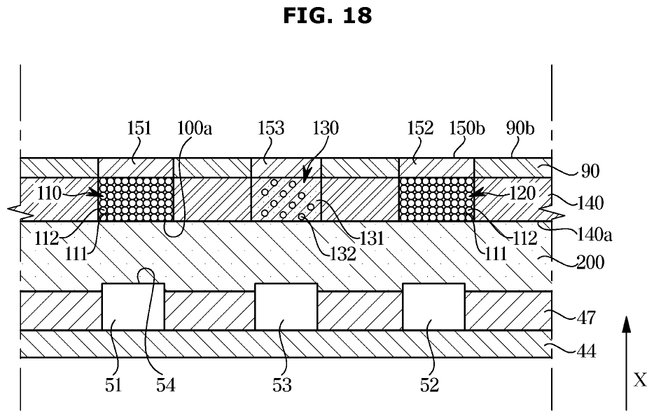

FIG. 8 is a flowchart illustrating a process of manufacturing a display module in a display apparatus according to an embodiment of the disclosure. FIG. 9 is a flowchart illustrating a process of manufacturing a color layer of a display module in a display apparatus according to an embodiment of the disclosure. FIG. 10 is a schematic view illustrating a process of manufacturing a display module in a display apparatus according to an embodiment of the disclosure. FIG. 11 is a schematic view illustrating a process of manufacturing a display module in a display apparatus according to an embodiment of the disclosure. FIG. 12 is a schematic view illustrating a process of manufacturing a display module in a display apparatus according to an embodiment of the disclosure. FIG. 13 is a schematic view illustrating a process of manufacturing a display module in a display apparatus according to an embodiment of the disclosure. FIG. 14 is a schematic view illustrating a process of manufacturing a display module in a display apparatus according to an embodiment of the disclosure. FIG. 15 is a schematic view illustrating a process of manufacturing a display module in a display apparatus according to an embodiment of the disclosure. FIG. 16 is a schematic view illustrating a process of manufacturing a display module in a display apparatus according to an embodiment of the disclosure. FIG. 17 is a schematic view illustrating a process of manufacturing a display module in a display apparatus according to an embodiment of the disclosure. FIG. 18 is a schematic view illustrating a process of manufacturing a display module in a display apparatus according to an embodiment of the disclosure.

Referring to FIGS. 8 and 10, a method of manufacturing the display module 30 in the display apparatus 1 according to an embodiment of the disclosure may include preparing a base substrate 300 (810). The base substrate 300 may include a first surface 300a and a second surface 300b that is opposite to the first surface 300a. For example, the base substrate 300 may be positioned such that the first surface 300a faces upward and the second surface 300b is supported by a flat floor, etc. For example, the base substrate 300 may be a glass substrate.

Referring to FIGS. 8 and 11, the method of manufacturing the display module 30 in the display apparatus 1 according to an embodiment of the disclosure may further include forming a sacrificial layer 310 on the base substrate 300 (820). The sacrificial layer 310 may be formed on the first surface 300a of the base substrate 300. For example, the sacrificial layer 310 may be applied directly onto the first surface 300a of the base substrate 300.

By radiating a laser onto the sacrificial layer 310 by a laser apparatus which will be described below, the sacrificial layer 310 may separate the base substrate 300 from a color layer 100. For example, the sacrificial layer 310 may be adhered to the color layer 100, and by radiating a laser onto the sacrificial layer 310, the sacrificial layer 310 may be evaporated to separate the base substrate 300 from the color layer 100 (see FIG. 17). For example, the laser may be a short wavelength laser.

The sacrificial layer 310 may be formed of a material that is evaporated by laser irradiation. For example, the sacrificial layer 310 may be formed of hydrogenated amorphous silicon (a-Si:H), amorphous gallium oxide (a-GaOₓ), amorphous gallium oxinitride (a-GaON), and lead zirconate titanate (Pb[ZrₓTi₁₋ₓ]O₃). For example, the sacrificial layer 310 may include at least one of a-Si:H, a-GaOₓ, a-GaON, or Pb[ZrₓTi₁₋ₓ]O₃.

The sacrificial layer 310 may be adhered to the color layer 100, and have a preset thickness d3 to prevent the color layer 100 from being damaged by laser irradiation. For example, the sacrificial layer 310 may have a thickness d3 of 50 nm to 200 nm. Also, a surface film 70 may be applied on the sacrificial layer 310, and because the sacrificial layer 310 has the preset thickness d3, any damage of the surface film 70 by a laser may be reduced.

The sacrificial layer 310 may include a first surface 310a and a second surface 310b that is opposite to the first surface 310a. For example, the first surface 310a of the sacrificial layer 310 may face upward and the second surface 310b of the sacrificial layer 310 may face downward to be in contact with the first surface 300a of the base substrate 300.

Referring to FIGS. 8, 9, and 12, the method of manufacturing the display module 30 in the display apparatus 1 according to an embodiment of the disclosure may further include forming the color layer 100 on the sacrificial layer 310 (830). The color layer 100 may be formed on the first surface 310a of the sacrificial layer 310. For example, the color layer 100 may be applied directly on the first surface 310a of the sacrificial layer 310.

Forming the color layer 100 in the display apparatus 1 according to an embodiment (830) may include forming a black matrix 90 on the sacrificial layer 310 (910). The color layer 100 may include the black matrix 90, and the black matrix 90 may be formed on the first surface 310a of the sacrificial layer 310. For example, the black matrix 90 may be formed directly on the first surface 310a of the sacrificial layer 310.

Black matrixes 90 may be arranged on the sacrificial layer 310 in such a way as to be spaced from each other. The black matrixes 90 may be spaced from each other to form a color filter accommodating space 90c in which the color filter 150 is positioned.

Each black matrix 90 may include a first surface 90a and a second surface 90b that is opposite to the first surface 90a. For example, the first surface 90a of the black matrix 90 may face upward and the second surface 90b of the black matrix 90 may face downward to be in contact with the first surface 310a of the sacrificial layer 310.

Referring to FIGS. 8, 9, and 13, forming the color layer 100 in the display apparatus 1 according to an embodiment of the disclosure (830) may further include forming a color filter 150 on the sacrificial layer 310 (920). The color filter 150 may be formed on the first surface 310a of the sacrificial layer 310. For example, the color filter 150 may be formed directly on the first surface 310a of the sacrificial layer 310. Forming the color filter 150 on the sacrificial layer 310 (920) may include forming the color filter 150 between the black matrixes 90 spaced from each other. Color filters 150 may be arranged on the sacrificial layer 310 in such a way as to be spaced from each other.

The color filter 150 may include a first surface 150a and a second surface 150b that is opposite to the first surface 150a. For example, the first surface 150a of the color filter 150 may face upward and the second surface 150b of the color filter 150 may face downward to be in contact with the first surface 310a of the sacrificial layer 310.

Referring to FIGS. 8, 9, and 14, forming the color layer 100 in the display apparatus 1 according to an embodiment (830) may further include forming a position guide 140 on the black matrix 90 (930). The position guide 140 may be formed on the first surface 90a of the black matrix 90. For example, the position guide 140 may be formed directly on the first surface 90a of the black matrix 90.

The position guide 140 may include a first surface 140a and a second surface 140b that is opposite to the first surface 140a. For example, the first surface 140a of the position guide 140 may face upward and the second surface 140b of the position guide 140 may face downward to be in contact with the first surface 90a of the black matrix 90.

Position guides 140 may be arranged on the black matrixes 90 in such a way as to be spaced from each other. The position guides 140 may be spaced from each other to form a space 140c in which the optical diffusion layer 110, 120, and 130 is formed. The space 140c may be an optical material accommodating space 140c accommodating a resin 111, 121, and 131 and a color conversion material 112 and 122. For example, the space 140c may be a color conversion material accommodating space 140c accommodating the color conversion material 112 and 122 and/or scattering particles 132.

Referring to FIGS. 8, 9, and 15, forming the color layer 100 in the display apparatus 1 according to an embodiment (830) may further include forming an optical diffusion layer 110, 120, and 130 on the color filter 150 (940).

The optical diffusion layer 110, 120, and 130 may be formed on the first surface 150a of the color filter 150. For example, the optical diffusion layer 110, 120, and 130 may be formed directly on the first surface 150a of the color filter 150. The optical diffusion layer 110, 120, and 130 may be provided in the optical material accommodating space 140c formed by the position guides 140. The optical diffusion layer 110, 120, and 130 may include the resin 111, 121, and 131, the color conversion material 112 and 122, and the scattering particles 132.

The optical diffusion layer 110, 120, and 130 may include a first surface 100a and a second surface 100b that is opposite to the first surface 100a. For example, the first surface 100a of the optical diffusion layer 110, 120, and 130 may face upward, and the second surface 100b of the optical diffusion layer 110, 120, and 130 may face downward to be in contact with the first surface 150a of the color filter 150.

Optical diffusion layers 110, 120, and 130 may be spaced from each other. The optical diffusion layers 110, 120, and 130 may be spaced from each other to correspond to the plurality of inorganic light-emitting devices 50, and the inorganic light-emitting devices 50 and the optical diffusion layers 110, 120, and 130 may form sub pixels.

Referring to FIGS. 8 and 16, the method of manufacturing the display module 30 in the display apparatus 1 according to an embodiment may further include adhering a light source substrate 40 to the color layer 100 such that inorganic light-emitting devices 50 face the color layer 100 (840). For example, the light source substrate 40 on which the inorganic light-emitting devices 50 are mounted may be adhered to the color layer 100 by using an adhesive layer 200.

The base substrate 300, the sacrificial layer 310, and the color layer 100 may be a first assembly, and the light source substrate 40 and the plurality of inorganic light-emitting devices 50 may be a second assembly. The method of manufacturing the display module 30 in the display apparatus 1 according to an embodiment may include adhering the first assembly to the second assembly by the adhesive layer 200.

The light source substrate 40 may be adhered to the color layer 100 such that a light emitting surface 54 of each of the plurality of inorganic light-emitting devices 50 faces the first surface 100a of the optical diffusion layer 110, 120, and 130. At this time, the light emitting surface 54 of the inorganic light-emitting device 50 may face downward.

Referring to FIGS. 8 and 17, the method of manufacturing the display module 30 in the display apparatus 1 according to an embodiment may further include radiating a laser to the sacrificial layer 310 to separate the base substrate 300 from the color layer 100 (850). For example, the display apparatus 1 according to an embodiment may remove the sacrificial layer 310 by using Laser Lift Off (LLO) to separate the base substrate 300 from the color layer 100. For example, by radiating a laser to the sacrificial layer 310 by a laser apparatus L, the base substrate 300 may be separated from the color filter 150 and the black matrix 90. For example, as a result of laser irradiation of the sacrificial layer 310, the sacrificial layer 310 may be evaporated and accordingly, the base substrate 300 may be separated from the color layer 100. For example, the laser may be a short wavelength laser having a laser wavelength of 200 nm to 350 nm.

By removing the sacrificial layer 310 and the base substrate 300 in a state in which the first assembly is adhered to the second assembly, the display module 30 may be completed.

Referring to FIG. 18, the method of manufacturing the display module 30 in the display apparatus 1 according to an embodiment may manufacture the display apparatus 1 including a display module array in which the plurality of display modules 30 are arranged horizontally in a matrix type by coupling the plurality of display modules 30 manufactured by the processes shown in FIGS. 10 to 17 to each other.

In the display module 30 according to an embodiment, the black matrix 90 and the color filter 150 may be positioned at a forefront of the display module 30, and the second surface 90b of the black matrix 90 and the second surface 150b of the color filter 150 may be a forefront surface of the display module 30.

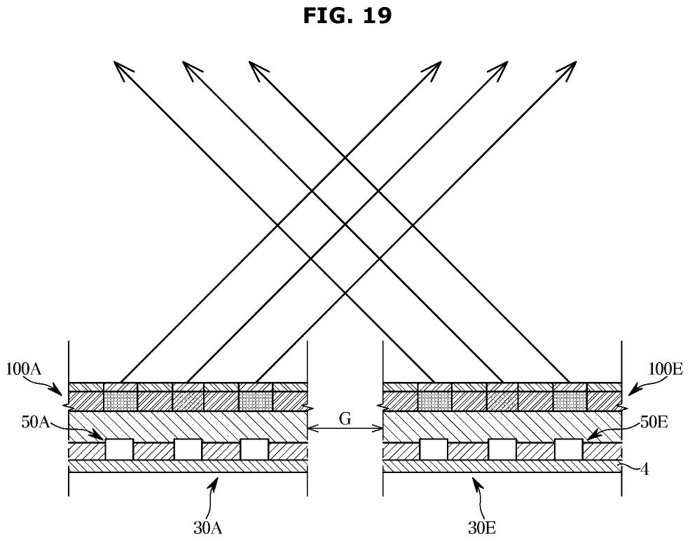

FIG. 19 is a cross-sectional view of a display apparatus according to an embodiment of the disclosure.

Referring to FIG. 19, the display apparatus 1 according to an embodiment of the disclosure may be manufactured by coupling the plurality of display modules 30A to 30P to each other, and gaps G may be formed between the plurality of display modules 30A to 30P. The first display module 30A and the second display module 30E positioned adjacent to the first display module 30A in the second direction Y will be described as examples.

According to an embodiment, because the base substrate 300 has been removed, light emitted from the inorganic light-emitting devices 50 may be neither refracted nor reflected at the gaps G between the display modules 30 and/or at outermost sides of the display modules 30 by the base substrate 300 or a separate glass substrate positioned on one side of the color layer 100.

For example, a phenomenon in which light refracted outward from each display module 30 is refracted and/or reflected by the base substrate 300 of an adjacent display module 30 and/or a separate glass substrate positioned at one side of the color layer 100 of the adjacent display module 30 to be recognized as strong light around a boundary and/or gap G between the display module 30 and the adjacent display module 30 may be prevented.

Also, because light emitted from the display module 30 is neither refracted nor reflected by the base substrate 300 and/or the separate glass substrate, the light may be emitted in the front direction. Accordingly, because brightness of the gaps G is little different from that of other areas, visibility of the gaps G may be reduced such that a user using the display apparatus 1 is not able to recognize the gaps G between the display modules 30. Also, because none of reflection and/or reflection occurs between the gaps G, the user may feel no image quality difference of the display apparatus 1 regardless of a position at which he/she views the display apparatus 1. As a result, the user's satisfaction in using the display apparatus 1 may be improved.

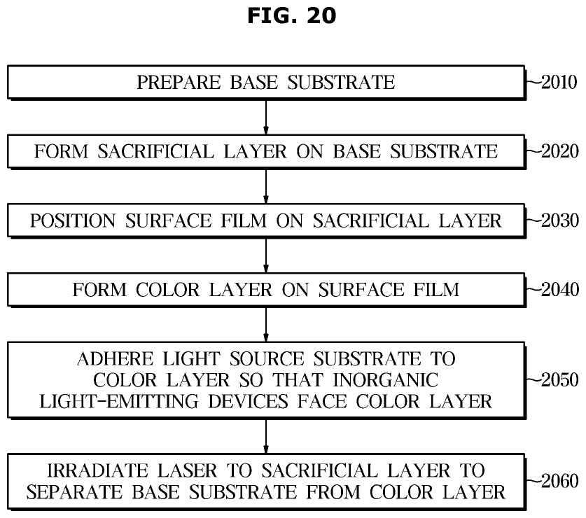

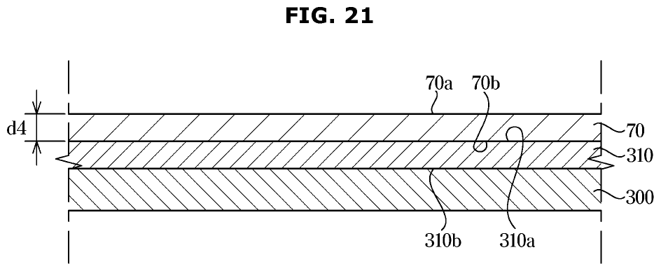

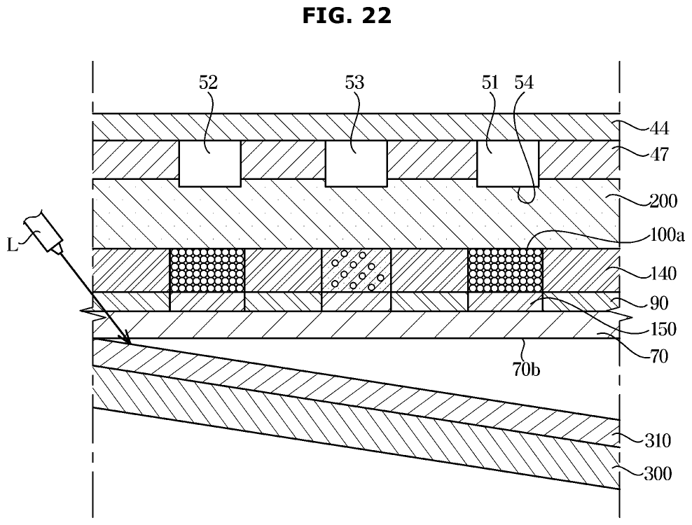

FIG. 20 is a flowchart illustrating a process of manufacturing a display module in a display apparatus according to an embodiment of the disclosure. FIG. 21 is a schematic view illustrating a process of manufacturing a display module in a display apparatus according to an embodiment of the disclosure. FIG. 22 is a schematic view illustrating a process of manufacturing a display module in a display apparatus according to an embodiment of the disclosure. FIG. 23 is a schematic view illustrating a process of manufacturing a display module in a display apparatus according to an embodiment of the disclosure.

Referring to FIGS. 20 and 21, the method of manufacturing the display module 30 in the display apparatus 1 according to an embodiment may include preparing a base substrate 300 (2010) and forming a sacrificial layer 310 on the base substrate 300 (2020).

Also, the method of manufacturing the display module 30 in the display apparatus 1 according to an embodiment may further include positioning a surface film 70 on the sacrificial layer 310 (2030).

The surface film 70 may be formed on a first surface 310a of the sacrificial layer 310. For example, the surface film 70 may be formed directly on the first surface 310a of the sacrificial layer 310.

The surface film 70 may include a first surface 70a and a second surface 70b that is opposite to the first surface 70a. For example, the first surface 70a of the surface film 70 may face upward, and the second surface 70b of the surface film 70 may face downward to be in contact with the first surface 310a of the sacrificial layer 310.

For example, the surface film 70 may include a low-reflection, anti-glare film and/or a non-glare film. A kind of the surface film 70 is not limited to this example. The surface film 70 may improve a contrast ratio and/or readability of the display apparatus 1, and reduce reflection caused by external light and glare caused by reflection generated inside the display modules 30. However, the kind of the surface film 70 is not limited to this example.

For example, the surface film 70 may include at least one of oxide beads, such as Silica (SiO) and/or Titanium Dioxide (TiO₂). However, ingredients of the surface film 70 are not limited to this example.

The surface film 70 may have a preset thickness d4. For example, the surface film 70 may have the thickness d4 of 100 micrometers (μm) or less. Because the surface film 70 has the thickness d4 of 100 micrometers (μm) or less, light reflection and/or refraction between the plurality of display modules 30 may be prevented. For example, the thickness d4 of the surface film 70 may be 100 micrometers (μm) or less at a resolution of 50 ppi of the display module 30. Also, for example, the thickness d4 of the surface film 70 may range from 50 micrometers (μm) to 80 micrometers (μm). According to the thickness d4 of the surface film 70 being 100 micrometers (μm) or less, light emitted from outermost sub pixels may not reach a threshold angle or less at which total reflection occurs at side surfaces of the surface film 70. Accordingly, the user may not recognize the gaps G by total reflection by the side surfaces of the surface film 70 and reflection or refraction between the display modules 30.

Also, in the display apparatus 1 having a resolution of 50 ppi or more, gaps between pixels may be reduced in reverse proportion of the resolution, and the thickness d4 of the surface film 70 may be further reduced. For example, at a resolution of 100 ppi, the surface film 70 may have the thickness d4 of 50 μm or less.

Referring to FIGS. 20 and 22, the method of manufacturing the display module 30 in the display apparatus 1 according to an embodiment may further include forming a color layer 100 on the surface film 70 (2040), adhering a light source substrate 40 to the color layer 100 such that inorganic light-emitting devices 50 face the color layer 100 (2050), and radiating a laser to the sacrificial layer 310 to separate the base substrate 300 from the color layer 100 (2060). For example, the color layer 100 on which the surface film 70 is positioned may be adhered to the light source substrate 40 on which the inorganic light-emitting devices 50 are mounted by using an adhesive layer 200.

Forming the color layer 100 on the surface film 70 (2040) may include forming black matrixes 90 on the surface film 70 (910), forming color filters 150 between the black matrixes 90 on the sacrificial layer 310 (920), forming position guides 140 on the black matrixes 90 (930), and forming light diffusion layers 110, 120, and 130 on the color filters 150 between the position guides 140 (940).

The base substrate 300, the sacrificial layer 310, the surface film 70, and the color layer 100 may be the first assembly, and the light source substrate 40 and the plurality of inorganic light-emitting devices 50 may be the second assembly. The method of manufacturing the display module 30 in the display apparatus 1 according to an embodiment may adhere the first assembly to the second assembly by the adhesive layer 200.

A light source substrate 40 may be adhered to the color layer 100 such that a light emitting surface 54 of each of the plurality of inorganic light-emitting devices 50 faces a first surface 100a of the light diffusion layer 110, 120, and 130. At this time, the light emitting surface 54 of each inorganic light-emitting device 50 may face downward.

Also, for example, the display apparatus 1 according to an embodiment may remove the sacrificial layer 310 by using LLO to separate the base substrate 300 from the color layer 100. Accordingly, by removing the sacrificial layer 310 and the base substrate 300 in a state in which the first assembly is adhered to the second assembly, the display module 30 may be completed.

Because the surface film 70 protects the color layer 100 although a laser is radiated, the black matrixes 90 and the color filters 150 may be prevented from being damaged during a manufacturing process.

Referring to FIG. 23, the method of manufacturing the display module 30 in the display apparatus 1 according to an embodiment may manufacture the display apparatus 1 including a display module array in which the plurality of display modules 30 are arranged horizontally in a matrix type by coupling the plurality of display modules 30 manufactured through the processes of FIGS. 20 to 22 to each other.

In the display module 30 according to an embodiment, the surface film 70 may be positioned at a forefront of the display module 30, and the second surface 70b of the surface film 70 may be a forefront surface of the display module 30.

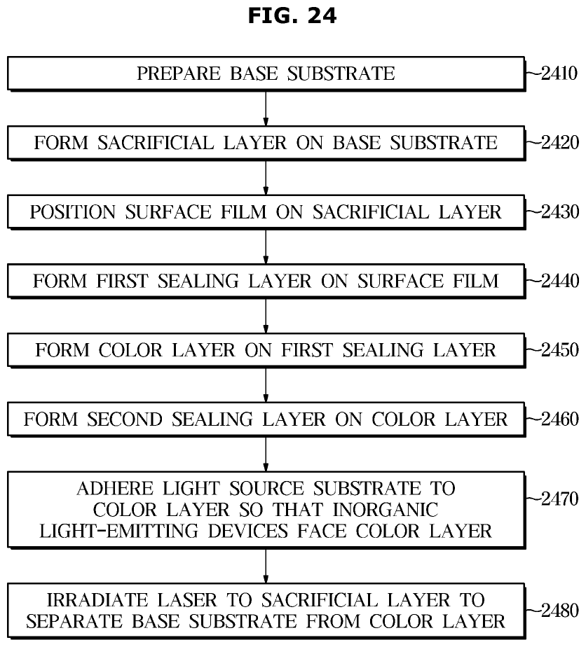

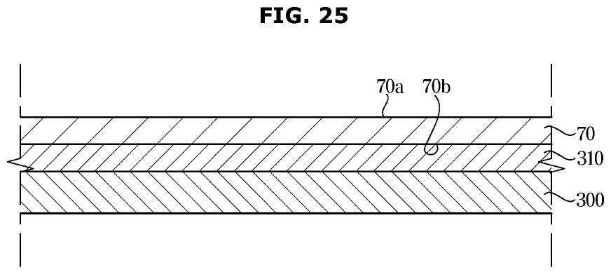

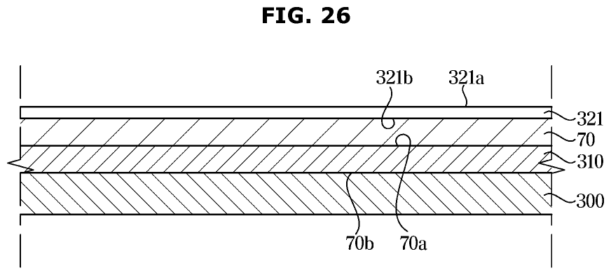

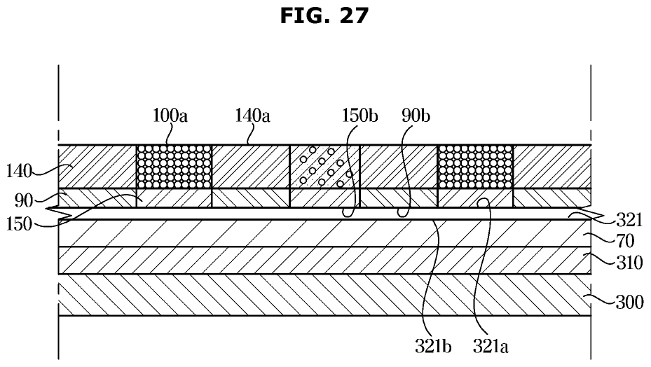

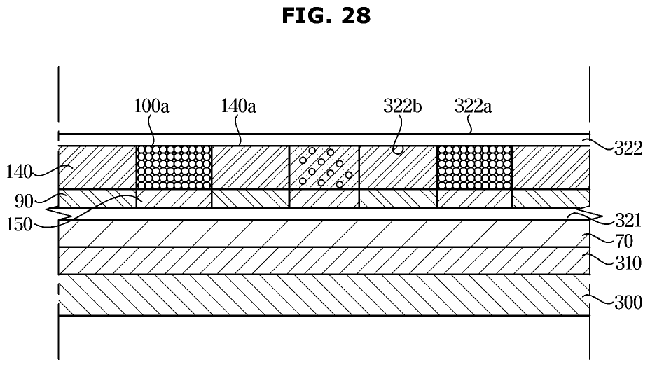

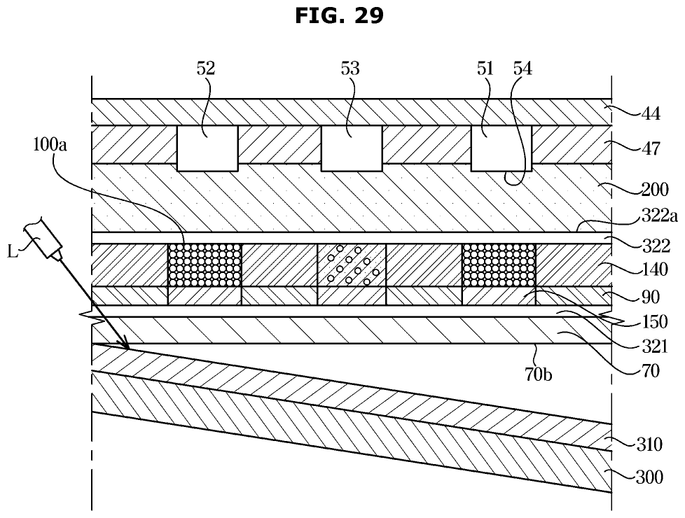

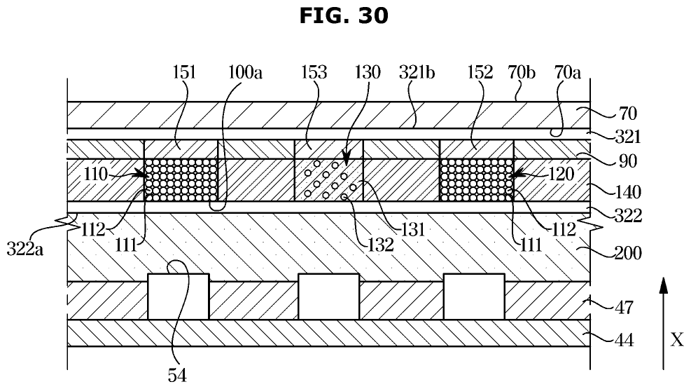

FIG. 24 is a flowchart illustrating a process of manufacturing a display module in a display apparatus according to an embodiment of the disclosure. FIG. 25 is a schematic view illustrating a process of manufacturing a display module in a display apparatus according to an embodiment of the disclosure. FIG. 26 is a schematic view illustrating a process of manufacturing a display module in a display apparatus according to an embodiment of the disclosure. FIG. 27 is a schematic view illustrating a process of manufacturing a display module in a display apparatus according to an embodiment of the disclosure. FIG. 28 is a schematic view illustrating a process of manufacturing a display module in a display apparatus according to an embodiment of the disclosure. FIG. 29 is a schematic view illustrating a process of manufacturing a display module in a display apparatus according to an embodiment of the disclosure. FIG. 30 is a schematic view illustrating a process of manufacturing a display module in a display apparatus according to an embodiment of the disclosure.

Referring to FIGS. 24 and 25, the method of manufacturing the display module 30 in the display apparatus 1 according to an embodiment may further include preparing a base substrate 300 (2410), forming a sacrificial layer 310 on the base substrate 300 (2420), and positioning a surface film 70 on the sacrificial layer 310 (2430). Each of the plurality of display modules 30A to 30P of the display apparatus 1 may include a sealing layer 321.

Referring to FIGS. 24 and 26, the method of manufacturing the display module 30 in the display apparatus 1 according to an embodiment may further include forming the sealing layer 321 on the surface film 70 (2440).

The sealing layer 321 may be formed on a first surface 70a of the surface film 70. For example, the sealing layer 321 may be formed directly on the first surface 70a of the surface film 70.

The sealing layer 321 may include a first surface 321a and a second surface 321b that is opposite to the first surface 321a. For example, the first surface 321a of the sealing layer 321 may face upward, and the second surface 321b of the sealing layer 321 may face downward to be in contact with the first surface 70a of the surface film 70.

The sealing layer 321 may include an inorganic material. The sealing layer 321 may be formed by depositing an inorganic material. For example, because the surface film 70 and a color layer 100 are formed of organic materials, the sealing layer 321 may be formed of an inorganic material to prevent water penetration between the organic materials. The sealing layer 321 may include at least one of SiO, Silicon Dioxide (SiO₂), Silicon Nitride (SiNₓ) or Silicon Oxide-Nitride (SiON). The sealing layer 321 may be formed of SiO, SiO₂, SiNₓ, and SiON. The sealing layer 321 may be a first sealing layer 321.

Referring to FIGS. 24 and 27, the method of manufacturing the display module 30 in the display apparatus 1 according to an embodiment may further include forming the color layer 100 on the first sealing layer 321 (2450). Forming the color layer 100 on the first sealing layer 321 (2450) may include positioning a color filter 150 and a color conversion material 112 and 122 on the sealing layer 321 (2450).

The color layer 100 may be formed on the first surface 321a of the first sealing layer 321. For example, the color layer 100 may be formed directly on the first surface 321a of the first sealing layer 321. For example, a second surface 90b of a black matrix 90 and a second surface 150b of a color filter 150 may be in contact with the first surface 321a of the first sealing layer 321.

Also, forming the color layer 100 (830, 2040, and 2450) may further include forming the black matrix 90 on the first sealing layer 321 (910) before positioning the color conversion material 112 and 122 on the first sealing layer 321.

Forming the color layer 100 (830, 2040, and 2450) may further include forming the color filter 150 between the black matrixes 90 on the sacrificial layer 310 (920) before positioning the color conversion material 112 and 122 on the first sealing layer 321 after forming the black matrixes 90 on the first sealing layer 321.

Forming the color layer 100 on the sacrificial layer 310 (830, 2040, and 2450) may further include forming a position guide 140 on the black matrix 90 to guide a position of the color filter 150 (930), before positioning the color conversion material 112 and 122 on the color filter 150 after forming the color filter 150 between the black matrixes 90.

Each of the plurality of display modules 30A to 30P of the display apparatus 1 may include a second sealing layer 322.

Referring to FIGS. 24 and 28, the method of manufacturing the display module 30 in the display apparatus 1 according to an embodiment may further include forming the second sealing layer 322 on the color layer 100 (2460). Forming the second sealing layer 322 on the color layer 100 (2460) may include positioning the second sealing layer 322 on the color conversion material 112 and 122 (2450).

The second sealing layer 322 may be formed on a first surface 100a and 140a of the color layer 100. The second sealing layer 322 may be formed on the first surface 100a of the optical diffusion layer 110, 120 and 130 and the first surface 140a of the position guide 140. For example, the second sealing layer 322 may be formed directly on the first surface 100a of the optical diffusion layer 110, 120, and 130 and the first surface 140a of the position guide 140.

The second sealing layer 322 may include a first surface 322a and a second surface 322b that is opposite to the first surface 322a. For example, the first surface 322a of the second sealing layer 322 may face upward, and the second surface 322b of the second sealing layer 322 may face downward to be in contact with the first surface 100a of the optical diffusion layer 110, 120, and 130 and the first surface 140a of the position guide 140.

The second sealing layer 322 may include an inorganic material. The second sealing layer 322 may be formed by depositing an inorganic material. For example, the second sealing layer 322 may be formed of an inorganic material to prevent water penetration between the first assembly and the second assembly. The second sealing layer 322 may include at least one of SiO, SiO₂, SiNₓ or SiON. The second sealing layer 322 may be formed of SiO, SiO₂, SiNₓ and SiON.

According to an embodiment of the disclosure, only one of the first sealing layer 321 or the second sealing layer 322 may be formed. For example, only the first sealing layer 321 may be formed to seal the surface film 70 while protecting the surface film 70. Also, for example, only the second sealing layer 322 may be formed to seal the color layer 100 while protecting the color layer 100.

The sealing layers 321 and 322 may be sealing members 321 and 322. For example, the first sealing layer 321 may be a first sealing member 321, and the second sealing layer 322 may be a second sealing member 322. Also, the first sealing layer 321 may be referred to as a second sealing member 321, and the second sealing layer 322 may be referred to as a first sealing member 322.

Referring to FIGS. 24 and 29, the method of manufacturing the display module 30 in the display apparatus 1 according to an embodiment may further include adhering a light source substrate 40 to the color layer 100 such that inorganic light-emitting devices 50 face the color layer 100 (2470), and radiating a laser to the sacrificial layer 310 to separate the base substrate 300 from the color layer 100 (2480). For example, the color layer 100 may be adhered to the light source substrate 40 on which the inorganic light-emitting devices 50 are mounted by using the adhesive layer 200. Adhering the light source substrate 40 to the color layer 100 (2470) may include adhering the light source substrate 40 to the second sealing layer 322 (2470).

Also, for example, the display apparatus 1 according to an embodiment may remove the sacrificial layer 310 by using LLO to separate the base substrate 300 from the color layer 100 (2480).

The base substrate 300, the sacrificial layer 310, the surface film 70, the first sealing layer 321, the color layer 100, and the second sealing layer 322 may be the first assembly, and the light source substrate 40 and the plurality of inorganic light-emitting devices 50 may be the second assembly. The method of manufacturing the display module 30 in the display apparatus 1 according to an embodiment may adhere the first assembly to the second assembly by the adhesive layer 200.

The light source substrate 40 may be adhered to the color layer 100 such that a light emitting surface 54 of each of the plurality of inorganic light-emitting devices 50 faces the first surface 100a of the optical diffusion layer 110, 120, and 130. At this time, the light emitting surface 54 of the inorganic light-emitting device 50 may face downward. The first surface 322a of the second sealing layer 322 may be adhered to the adhesive layer 200.

By removing the sacrificial layer 310 and the base substrate 300 in a state in which the first assembly is adhered to the second assembly, the display module 30 may be completed.

Referring to FIG. 30, the method of manufacturing the display module 30 in the display apparatus 1 according to an embodiment may manufacture the display apparatus 1 including a display module array in which the plurality of display modules 30 are arranged horizontally in a matrix type by coupling the plurality of display modules 30 manufactured through the processes shown in FIGS. 24 to 29 to each other.

In the display module 30 according to an embodiment, the surface film 70 may be positioned at a forefront of the display module 30, and the second surface 70b of the surface film 70 may be a forefront surface of the display module 30.

Although the sealing layers 321 and 322 have been described as components not included in the color layer 100, the sealing layers 321 and 322 may be components included in the color layer 100. For example, the first surface of the color layer 100 may be the first surface 322a of the sealing layers 321 and 322, or the second surface of the color layer 100 may be the second surface 321b of the sealing layers 321 and 322. Accordingly, the second surface 321b of the color layer 100 may be in contact with the first surface 70a of the surface film 70, and the first surface 322a of the color layer 100 may be in contact with the adhesive layer 200.

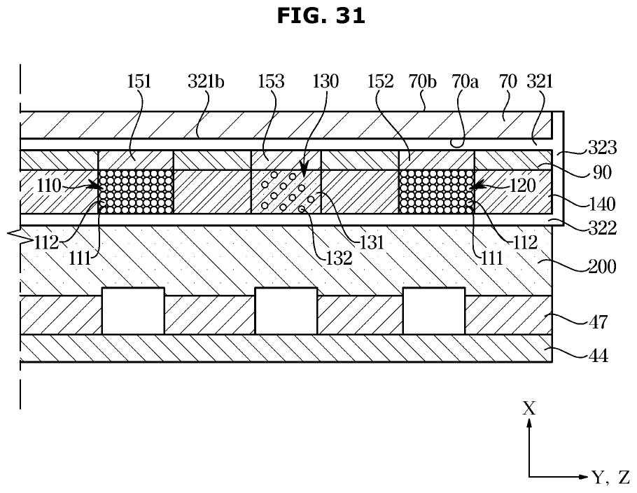

FIG. 31 is a cross-sectional view of a display apparatus according to an embodiment of the disclosure. FIG. 31 is a cross-sectional view schematically showing one end of a display module.

Referring to FIG. 31, the display apparatus 1 according to an embodiment may further include a third sealing member 323. The third sealing member 323 may be positioned at an outer end of each of the plurality of display modules 30A to 30P. The third sealing member 323 may be positioned at the outer end of the display module 30 in the second direction Y and/or the third direction Z to protect the surface film 70 and the color layer 100 while sealing the surface film 70 and the color layer 100. Accordingly, the third sealing member 323 may prevent water penetration into the color layer 100 from the outside of the display module 30 and prevent failure of the display module 30.

The third sealing member 323 may include an inorganic material. The third sealing member 323 may be formed by depositing an inorganic material. The third sealing member 323 may include at least one of SiO, SiO₂, SiNₓ or SiON. The third sealing member 323 may be formed of SiO, SiO₂, SiNₓ and SiON.

For example, a portion of the third sealing member 323 may be formed while the first sealing member 321 is formed, and another portion of the third sealing member 323 may be formed while the second sealing member 322 is formed.

Also, according to an embodiment of the disclosure, the third sealing member 323 may be formed only while one of the first sealing member 321 or the second sealing member 322 is formed. For example, the third sealing member 323 may be formed only while the first sealing member 321 is formed, to seal the surface film 70 while protecting the surface film 70. Also, for example, the third sealing member 323 may be formed only while the second sealing member 322 is formed, to seal the color layer 100 while protecting the color layer 100.

In a method of manufacturing a display apparatus 1 including a display module array in which a plurality of display modules 30 are arranged horizontally in a matrix type, according to an embodiment, a method of manufacturing each of the plurality of display modules 30 may include forming a sacrificial layer 310 on a base substrate 300 (820, 2020, and 2420), forming a color filter 150 on the sacrificial layer 310 (830 and 920), positioning quantum dots 112 and 122 on the color filter 150 (940) to form a color layer 100 (830, 2040, and 2450), adhering a light source substrate 40 in which inorganic light-emitting devices 50 are positioned to the color layer 100 so that the inorganic light-emitting devices 50 face the color layer 100 (840, 2050, and 2470), and radiating a laser to the sacrificial layer 310 to separate the base substrate 300 from the color layer 100 (850, 2060, and 2480).

Positioning a surface film 70 on the sacrificial layer 310 (2030 and 2430) before forming the color filter 150 on the sacrificial layer 310 (920) may be further included, and forming the color layer 100 (830, 2040, and 2450) may include forming the color filter 150 on the surface film 70 (2040 and 2450).

Forming the color layer 100 (830, 2040, and 2450) may further include forming an optical diffusion layer 110, 120, and 130 on the surface film 70 (940).

Forming a sealing layer 321 on the color filter 150 (2440) before forming the optical diffusion layer 110, 120, and 130 including the quantum dots 112 and 122 on the surface film 70 may be further included.

Forming the color layer 100 (830, 2040, and 2450) may further include forming the color layer 100 by positioning the quantum dots 112 and 122 on the sealing layer 321 (2450) after forming the sealing layer 321 on the surface film 70.

The sealing layer 321 may be a first sealing layer 321, and forming a second sealing layer 322 on the color layer 100 (2460) may be further included.

Forming the color layer 100 (830, 2040, and 2450) may further include forming black matrixes 90 on the first sealing layer 321 (910) before positioning the quantum dots 112 and 122 on the first sealing layer 321.

Forming the color layer 100 (830, 2040, and 2450) may further include forming the color filter 150 between the black matrixes 90 (920) before positioning the quantum dots 112 and 122 on the first sealing layer 321 and after forming the black matrixes 90 on the first sealing layer 321.

Forming the color layer 100 (830, 2040, and 2450) may further include forming position guides 140 on the black matrixes 90 to guide a position of the color filter 150 (930), before positioning the quantum dots 112 and 122 on the color filter 150 and after forming the color filter 150 between the black matrixes 90, wherein the color filter 150 may be positioned between the position guides 140.

Adhering the light source substrate 40 onto the second sealing layer 322 so that the inorganic light-emitting devices 50 face the color layer 100 (2470) may be further included.

Radiating a laser to separate the base substrate 300 from the color layer 100 may include separating the base substrate 300 from the color layer 100 by using LLO having a short wavelength (850, 2060, and 2480).

The laser may have a wavelength of 200 nm to 350 nm.

The sacrificial layer 310 may include at least one of a-Si:H, a-GaOₓ, a-GaON, or Pb[ZrₓTi₁₋ₓ]O₃, and the sacrificial layer 310 may have a thickness of 50 nm to 200 nm.

The thickness of the sacrificial layer 310 may be 100 micrometers (μm) or less.

The first sealing layer 321 and the second sealing layer 322 may include at least one of SiO, SiO₂, SiNₓ, or SiON.

In a display apparatus including a display module array in which a plurality of display modules 30 are arranged horizontally in a matrix type, according to an embodiment, each of the plurality of display modules 30 may include a substrate 40, inorganic light-emitting devices 50 mounted on the substrate 40, a color layer 100 including a first surface 100a, 140a, and 322a through which light emitted from the inorganic light-emitting devices 50 passes and which faces the inorganic light-emitting devices 50, and a second surface 90b, 150b, and 321b that is opposite to the first surface, and a surface film 70 of which one surface 70a is in contact with the second surface 90b, 150b, and 321b of the color layer 100 and which is positioned on the color layer 100 to reduce glare caused by reflection.

The surface film 70 may include at least one of a silicon resin, PMMA, or PDMS, and the surface film 70 may have a thickness of 100 micrometers (μm) or less.

The color layer 100 may further include a sealing layer 321 being in contact with the one surface 70a of the surface film 70.

Each of the plurality of display modules 30 may further include an adhesive layer 200 positioned between the substrate 40 and the color layer 100, the sealing layer 321 may be a first sealing layer 321, and the color layer 100 may further include an optical diffusion layer 110, 120, and 130 positioned between the inorganic light-emitting devices 50 and the first sealing layer 321 and a second sealing layer 322 positioned between the optical diffusion layer 110, 120, and 130 and the adhesive layer 200.

A display apparatus according to an embodiment may include a substrate 40 including a mounting surface 41, inorganic light-emitting devices 50 electrically connected to the mounting surface 41 and including a first inorganic light-emitting device 51, a second inorganic light-emitting device 52, and a third inorganic light-emitting devices 53, a first color conversion layer 110 positioned in front of the inorganic light-emitting devices 50, wherein light emitted from the first inorganic light-emitting device 51 passes through the first color conversion layer 110, a second color conversion layer 120, wherein light emitted from the second inorganic light-emitting device 52 passes through the second color conversion layer 120, a scattering layer 130, wherein light emitted from the third inorganic light-emitting device 53 passes through the scattering layer 130, an optical layer 110, 120, and 130 including scattering particles positioned inside the scattering layer 130, a black matrix 90 positioned in front of the optical layer 110, 120, and 130, and a surface film 70 positioned in front of the black matrix 90.

According to an aspect of the disclosure, a display apparatus capable of preventing light emitted from inorganic light-emitting devices from being refracted and reflected between a plurality of display modules without any substrate in front of the inorganic light-emitting devices may be provided.

According to an aspect of the disclosure, because refraction and reflection of light between the plurality of display modules are prevented, a display apparatus capable of reducing visible seams between the plurality of display modules may be provided.

According to an aspect of the disclosure, a display apparatus capable of simplifying processes because a surface film and a sealing layer are positioned on a color layer to eliminate a need for additional surface treatment or sealing in the subsequent processes, and preventing water penetration into display modules may be provided.

Effects that may be achieved according to an aspect of the disclosure are not limited to the above-mentioned effects, and other effects not mentioned will be clearly understood by one of ordinary skill in the technical field to which the disclosure belongs from the following descriptions.

Although specific embodiments have been shown and described, the disclosure is not limited to the above-described embodiments, and various modifications can be made by those skilled in the art without departing from the gist of the technical idea of the disclosure defined by the claims below.

What is claimed is:

1. A method of manufacturing a display module of a display apparatus, the method comprising:
forming a sacrificial layer on a base substrate;
forming a color filter on the sacrificial layer;
forming a color layer by positioning quantum dots on the color filter;
adhering to the color layer a light source substrate on which an inorganic light-emitting device is positioned so that the inorganic light-emitting device faces the color layer; and
separating the base substrate from the color layer by irradiating the sacrificial layer with laser light.

2. The method of claim 1, further comprising positioning a surface film on the sacrificial layer before forming the color filter on the sacrificial layer,
wherein the forming the color layer comprises forming the color filter on the surface film.

3. The method of claim 2, wherein the forming the color layer further comprises forming an optical diffusion layer on the color filter, wherein the optical diffusion layer comprises the quantum dots.

4. The method of claim 3, further comprising forming a sealing layer on the surface film before forming the optical diffusion layer on the surface film.

5. The method of claim 4, wherein the forming the color layer further comprises positioning the quantum dots on the sealing layer after forming the sealing layer on the surface film.

6. The method of claim 5, wherein the sealing layer is a first sealing layer, and
wherein the method further comprises forming a second sealing layer on the color layer.

7. The method of claim 6, wherein the forming the color layer further comprises forming a black matrix on the first sealing layer before positioning the quantum dots on the first sealing layer.

8. The method of claim 7, wherein the forming the color layer further comprises forming the color filter in a plurality of spaces formed between the black matrix before positioning the quantum dots on the first sealing layer and after forming the black matrix on the first sealing layer.

9. The method of claim 8, wherein the forming of the color layer further comprises forming a plurality of position guides on the black matrix to guide a position of the color filter before positioning the quantum dots on the color filter and after forming the color filter in the plurality of spaces between the black matrix, and
wherein the color filter is positioned between the plurality of position guides.

10. The method of claim 9, further comprising adhering the light source substrate to the second sealing layer.

11. The method of claim 1, wherein the separating the base substrate from the color layer comprises separating the base substrate from the color layer by using Laser Lift Off.

12. The method of claim 11, wherein a wavelength of the laser light ranges from 200 nm to 350 nm.

13. The method of claim 1, wherein the sacrificial layer comprises at least one of hydrogenated amorphous silicon, amorphous gallium oxide, amorphous gallium oxinitride, and lead zirconate titanate, and
wherein a thickness of the sacrificial layer ranges from 50 nm to 200 nm.

14. The method of claim 2, wherein a thickness of the surface film is less than or equal to 100 micrometers.

15. The method of claim 6, wherein each of the first sealing layer and the second sealing layer comprises at least one of silica, silicon dioxide, silicon nitride or silicon oxide-nitride.

16. A method of manufacturing a display module of a display apparatus, the method comprising:
forming a sacrificial layer on a base substrate;
forming a black matrix on the sacrificial layer, wherein the black matrix defines a first plurality of spaces;
forming a color filter on the sacrificial layer in the first plurality of spaces;
forming a color layer on the color filter;
adhering to the color layer a light source substrate on which an inorganic light-emitting device is positioned so that the inorganic light-emitting device faces the color layer; and
separating the base substrate from the color layer by radiating laser light onto the sacrificial layer.

17. The method of claim 16, wherein the forming the color layer on the color filter further comprises:
forming a plurality of position guides on the black matrix, wherein a second plurality of spaces are formed between the plurality of position guides, and wherein the second plurality of spaces align with the first plurality of spaces; and
forming an optical diffusion layer on the color filter in the second plurality of spaces.

18. The method of claim 17, wherein the optical diffusion layer comprises quantum dots formed on the color filter in the second plurality of spaces.

19. The method of claim 18, wherein the forming the color filter further comprises forming a surface film on the color filter, and
wherein the color layer is formed on the surface film.

20. A method of manufacturing a display module of a display apparatus, the method comprising:
forming a sacrificial layer on a base substrate;
forming a black matrix on the sacrificial layer, wherein the black matrix defines a first plurality of spaces;
forming a color filter on the sacrificial layer in the first plurality of spaces;
forming a surface film on the color filter;
forming a color layer on the surface film by positioning quantum dots on the surface film, wherein the quantum dots align with the color filter;
adhering to the color layer a light source substrate on which an inorganic light-emitting device is positioned so that the inorganic light-emitting device faces the color layer; and
separating the base substrate from the color layer by radiating laser light onto the sacrificial layer.
